(19) United States
(12) Patent Application Publication
(10) Pub. No.: US 2026/0344148 A1
(43) Pub. Date: Oct. 29, 2026

(54) DISPLAY DEVICE

(71) Applicants: LG ELECTRONICS INC., Seoul (KR); LG DISPLAY CO., LTD., Seoul (KR)

(72) Inventors: Jaewon CHANG, Seoul (KR); Wonseok CHOI, Seoul (KR)

(73) Assignees: LG ELECTRONICS INC., Seoul (KR); LG DISPLAY CO., LTD., Seoul (KR)

(21) Appl. No.: 19/111,599

(22) PCT Filed: Sep. 16, 2022
(86) PCT No.: PCT/KR2022/013849

§ 371 Date: Mar. 13, 2025

(51) Int. Cl. H10H 29/49

(52) U.S. Cl. CPC H10H 29/49

(57) ABSTRACT

The display device may include a plurality of pixels. Each of the plurality of pixels may include a substrate comprising a plurality of subpixels, a first assembly wiring and a second assembly wiring in each of the plurality of subpixels, a partition wall having an assembly hole on the first assembly wiring and the second assembly wiring, a semiconductor light-emitting element in the assembly hole, and a signal supply unit configured to be connected to the first assembly wiring and the second assembly wiring and to selectively supply an AC signal and a DC signal.

### TECHNICAL FIELD

The embodiment relates to a display device.

### BACKGROUND ART

A large-area display comprises a liquid crystal display (LCD), an OLED display, and a micro-LED display.

A micro-LED display is a display that uses micro-LEDs, which are semiconductor light-emitting elements with a diameter or cross-sectional area of 100um or less, as display elements.

Since a micro-LED display uses micro-LEDs, which are semiconductor light-emitting elements, as display elements, it has excellent performance in many characteristics such as contrast ratio, response speed, color reproducibility, viewing angle, brightness, resolution, lifespan, luminous efficiency, and luminance.

In particular, a micro-LED display has the advantage of being able to freely adjust the size or resolution because the screen may be separated and combined in a modular manner, and it has the advantage of being able to implement a flexible display.

However, since a large-area micro-LED display requires millions or more micro-LEDs, there is a technical problem that it is difficult to quickly and accurately transfer micro-LEDs to a display panel.

Recently developed transfer technologies include the pick and place process, the laser lift-off method, and the self-assembly method.

Among these, the self-assembly method is a method in which semiconductor light-emitting elements find their assembly positions in a fluid, which is advantageous for implementing a large-screen display device.

However, research on the technology for manufacturing displays through self-assembly of micro-LEDs is still insufficient.

In particular, in the conventional technology, when millions or more semiconductor light-emitting elements are quickly transferred to a large display, the transfer speed may be improved, but the transfer error rate may increase, which causes a technical problem in that the transfer yield is low.

In the related technology, a self-assembly transfer process using dielectrophoresis (DEP) is being attempted, but there is a problem in that the self-assembly rate is low due to the unevenness of the DEP force.

Meanwhile, a pixel is divided into a red subpixel, a green subpixel, and a blue subpixel, and color images are implemented using light provided from these subpixels, respectively.

In order to implement a display device, a plurality of subpixels included in each of a plurality of pixels must be selectively controlled, so that for this selective control, each subpixel is equipped with various transistors as well as a light-emitting diode.

Recently, precise control of the light-emitting diode is required to implement improved image quality, and more and more transistors may be provided in each subpixel to meet this requirement. When the number of transistors increases, the design complexity for the transistors increases, which reduces the yield and increases the manufacturing cost.

Recently, high resolution is required for clear image quality, and the size of pixels is reduced to meet this requirement, so that the size of each subpixel is also reduced. However, while the size of each subpixel is decreasing, the number of transistors added to each subpixel is increasing. In order to solve this problem, the size of a non-light-emitting region within the subpixel must increase, so that the size of a light-emitting region decreases in inverse proportion. When the size of the light-emitting region decreases, there is a problem that the image quality characteristics, i.e., visibility, degrades due to the decrease in an aperture ratio. When the size of the light-emitting region decreases, there is a problem that the luminance of the light provided from each subpixel decreases. Therefore, a method that precisely controls the light-emitting diodes without increasing the number of transistors is urgently required.

Meanwhile, in the conventional display device, the transistors provided in each subpixel are manufactured using LTPS-based transistors. However, the LTPS-based transistors essentially require a crystallization process using a laser, and during this crystallization process, the unstable output of the laser causes the gate voltages of the transistors of each subpixel to be different from each other. Since the threshold voltage is related to the driving current that drives the light-emitting diode, when the threshold voltage is different, the driving current of the light-emitting diode is different for each subpixel. For example, in order to generate light representing 255 grayscales in each subpixel, a data voltage corresponding to 255 grayscales may be provided to each subpixel. In this instance, the driving current of each subpixel is different due to the different transistor voltages for each subpixel, so that light with a grayscale of 255 or less is generated for each subpixel. Therefore, there is a problem of uneven luminance for each subpixel.

Meanwhile, since a circuit for assembling a semiconductor light-emitting element and a circuit for emitting light from the semiconductor light-emitting element are provided during self-assembly, there is a problem that the circuit structure is very complicated.

Since aging is not performed to resolve luminance unevenness between each subpixel before the product shipment of the display device, there is a problem that the image quality degrades after the product shipment.

In addition, when an image is displayed for a long time after the product shipment of the display device, the luminance unevenness between each subpixel naturally occurs, but a circuit structure for solving this has not yet been presented.

### DISCLOSURE

### Technical Problem

An object of the embodiment is to solve the foregoing and other problems.

Another object of the embodiment is to provide a display device having a circuit structure capable of self-assembly.

In addition, another object of the embodiment is to provide a display device having a circuit structure capable of aging.

In addition, another object of the embodiment is to provide a display device having a circuit structure capable of preventing luminance unevenness.

In addition, another object of the embodiment is to provide a display device having a circuit structure in which the number of transistors per subpixel is reduced in order to implement high resolution.

The technical problems of the embodiments are not limited to those described in this item and comprise those that may be understood through the description of the invention.

### Technical Solution

In order to achieve the above or other objects, according to one aspect of the embodiment, a display device, comprising: a substrate comprising a plurality of pixels, each of the plurality of pixels comprising a plurality of subpixels; a first assembly wiring and a second assembly wiring in each of the plurality of subpixels; a partition wall having an assembly hole on the first assembly wiring and the second assembly wiring; a semiconductor light-emitting element in the assembly hole; and a signal supply unit configured to be connected to the first assembly wiring and the second assembly wiring and to selectively supply an AC signal and a DC signal.

When the semiconductor light-emitting element is self-assembled, the signal supply unit may supply the AC signal to the first assembly wiring and the second assembly wiring.

The display device may comprise a subpixel circuit in each of the plurality of subpixels, the subpixel circuit may be connected to one of the first assembly wiring and the second assembly wiring, the first assembly wiring may be connected to a first side of the semiconductor light-emitting element, and the second assembly wiring may be connected to a second side of the semiconductor light-emitting element.

When the semiconductor light-emitting element emits light, the subpixel circuit may supply a driving current to one of the first assembly wiring and the second assembly wiring.

The subpixel circuit may comprise a first transistor between a first signal line, a second signal line, and a first node; a second transistor between the first signal line, a third signal line, and a second node; a third transistor between the first node, a power line, and the second node; and a capacitor between the first node and the second node.

The subpixel circuit may comprise a fourth transistor between a fourth signal line, the second node, and a third node.

When the semiconductor light-emitting element is aged, the fourth transistor may be turned off, and the signal supply unit may supply the DC signal to the first assembly wiring and the second assembly wiring.

signal supply unit may comprise an AC signal generator configured to generate the AC signal; a DC signal generator configured to generate the DC signal; a signal selector configured to selectively output the AC signal and the DC signal; and a switching unit configured to control supply of an output signal of the signal selector.

The switching unit may comprise a fifth transistor configured to switch supply of a first voltage of the output signal to the first assembly wiring; and a sixth transistor configured to switch supply of a second voltage of the output signal to the second assembly wiring.

When the semiconductor light-emitting element is self-assembled, the fifth transistor and the sixth transistor may be turned on to supply the AC signal selected by the signal selector.

When the semiconductor light-emitting element is aged, the fifth transistor and the sixth transistor may be turned on to supply the DC signal selected by the selector.

When the semiconductor light-emitting element emits light, the fifth transistor and the sixth transistor may be turned off to block supply of the AC signal or the DC signal selected by the selector.

The AC signal generator, the DC signal generator, and the signal selector may be provided on a non-display region.

The switching unit may be provided on a non-display region.

The switching unit may be provided in each of the plurality of subpixels.

The display device may comprise an input interface, and the signal supply unit may supply the DC signal to the semiconductor light emitting element in response to an aging signal through the input interface.

### Advantageous Effects

As illustrated in FIG. 7, a signal supply unit 400 that selectively supplies an AC signal ACS and a DC signal DCS may be provided.

As illustrated in FIGS. 9 and 10, each of a plurality of subpixels PX1, PX2, and PX3 may comprise a subpixel circuit 230 and a semiconductor light-emitting element 150-1. The semiconductor light-emitting element 150-1 may be connected to a first assembly wiring 321 and a second assembly wiring 322.

The subpixel circuit 230 may be connected to the first assembly wiring 321 or the second assembly wiring 322. The subpixel circuit 230 may generate a driving current and may supply it to the semiconductor light-emitting element 150-1, so that the semiconductor light-emitting element 150-1 may emit light.

The signal supply unit 400 may be connected to the first assembly wiring 321 and the second assembly wiring 322, and may supply an AC signal ACS or a DC signal DCS to the first assembly wiring 321 and the second assembly wiring 322.

As an example, the AC signal ACS may be supplied to the first assembly wiring 321 and the second assembly wiring 322, so that a DEP force may be formed in the assembly hole 340H1, and the semiconductor light-emitting element 150-1 may be assembled into the assembly hole 340H1 by the DEP force.

For example, the DC signal DCS may be supplied to the semiconductor light-emitting element 150-1 via the first assembly wiring 321 and the second assembly wiring 322 of each of the plurality of subpixels PX1, PX2, and PX3, so that the semiconductor light-emitting element 150-1 may be aged, thereby improving the image quality.

As described above, when the AC signal ACS or the DC signal DCS is supplied from the signal supply unit 400 to the first assembly wiring 321 and the second assembly wiring 322 for self-assembly or aging, a fourth transistor T4 of the subpixel circuit 230 may be turned off, so that the AC signal ACS or the DC signal DCS supplied to the first assembly wiring 321 and the second assembly wiring 322 may be not supplied to the subpixel circuit 230, thereby preventing damage to the electronic circuit or electronic components of the subpixel circuit 230.

In the embodiment, the number of transistors can be minimized to implement high resolution.

In the embodiment, the image quality can be improved through aging.

In the embodiment, the circuit structure can be simplified by performing the supply of a signal for self-assembly or aging from the same circuit source, i.e., the signal supply unit 400.

Additional scope of applicability of the embodiments will become apparent from the detailed description that follows. However, since various changes and modifications within the idea and scope of the embodiments may be clearly understood by those skilled in the art, the detailed description and specific embodiments, such as preferred embodiments, should be understood as being given by way of example only.

### DESCRIPTION OF DRAWINGS

FIG. 1 illustrates a living room of a house in which a display device according to an embodiment is disposed.

FIG. 2 is a block diagram schematically showing a display device according to an embodiment.

FIG. 3 is a circuit diagram showing an example of pixels of FIG. 2.

FIG. 4 is an enlarged view of a first panel region in the display device of FIG. 1.

FIG. 5 is an enlarged view of a region A2 of FIG. 4.

FIG. 6 is a diagram illustrating an example in which a light-emitting element according to an embodiment is assembled on a substrate by a self-assembly method.

FIG. 7 is a circuit diagram illustrating a display device according to an embodiment.

FIG. 8 is a block diagram illustrating a signal supply unit of an embodiment.

FIG. 9 illustrates a connection relationship between a first subpixel and a signal supply unit.

FIG. 10 is a circuit diagram illustrating a first subpixel according to a first embodiment.

FIG. 11 is a signal waveform diagram for an operation of a first subpixel.

FIG. 12 illustrates an operation of a first subpixel during self-assembly.

FIG. 13 illustrates the form in which DEP force is formed in a first subpixel during self-assembly.

FIG. 14 illustrates the assembly of a semiconductor light-emitting element in a first subpixel during self-assembly.

FIGS. 15 and 16 illustrate a light-emitting operation of a semiconductor light-emitting element of a first subpixel.

FIG. 17 illustrates an aging operation of a semiconductor light-emitting element of a first subpixel.

FIG. 18 illustrates a fourth transistor being turned on during an aging operation of a semiconductor light-emitting element of a first subpixel.

FIG. 19 is a circuit diagram illustrating a first subpixel according to a second embodiment.

The sizes, shapes, dimensions, etc. of elements illustrated in the drawings may differ from actual ones. In addition, even if the same elements are illustrated in different sizes, shapes, dimensions, etc. between the drawings, this is only an example on the drawing, and the same elements have the same sizes, shapes, dimensions, etc. between the drawings.

### MODE FOR INVENTION

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, region or substrate is referred to as being ‘on’ another element, this means that there may be directly on the other element or be other intermediate elements therebetween.

The display device described in this specification may comprise a TV, a signage, a mobile terminal such as a mobile phone or a smart phone, a computer display such as a laptop or a desktop, a head-up display (HUD) for an automobile, a backlight unit for a display, a display for VR, AR or mixed reality (MR), a light source, etc. However, the configuration according to the embodiment described in this specification may also be applied to a device capable of displaying, even if it is a new product type developed in the future.

Hereinafter, a light-emitting element according to an embodiment and a display device comprising the same will be described.

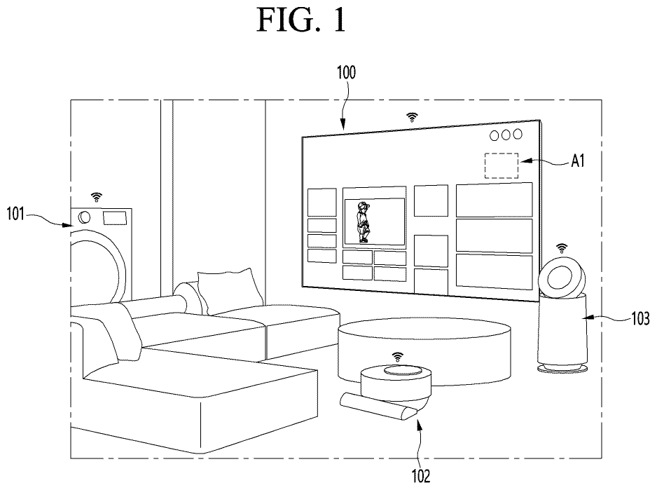

FIG. 1 illustrates a living room of a house in which a display device according to an embodiment is disposed.

Referring to FIG. 1, the display device 100 according to the embodiment may display the status of various electronic products such as a washing machine 101, a robot vacuum cleaner 102, and an air purifier 103, and may communicate with each electronic product based on IoT and control each electronic product based on the user's setting data.

The display device 100 according to the embodiment may comprise a flexible display manufactured on a thin and flexible substrate. The flexible display may be bent or rolled like paper while maintaining the characteristics of an existing flat display.

In the flexible display, visual information may be implemented by independently controlling the light emission of unit pixels disposed in a matrix form. A unit pixel means a minimum unit for implementing one color. The unit pixel of the flexible display may be implemented by a light-emitting element. In the embodiment, the light-emitting element may be a micro-LED or a nano-LED, but is not limited thereto.

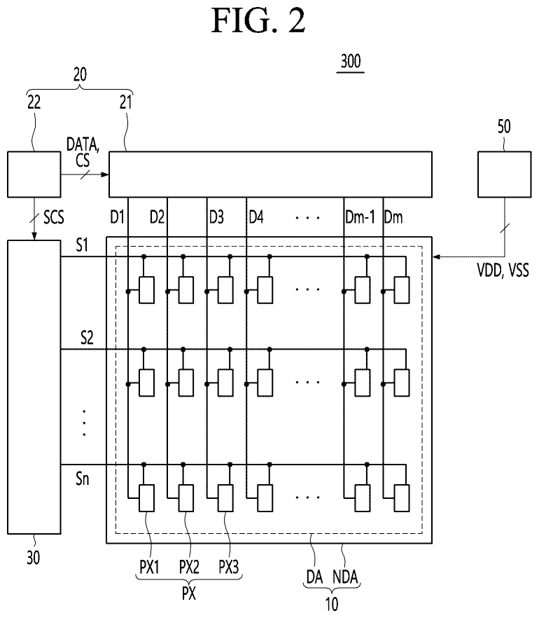

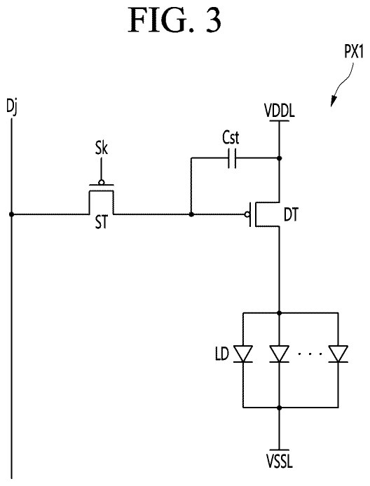

FIG. 2 is a block diagram schematically showing a display device according to an embodiment, and FIG. 3 is a circuit diagram showing an example of pixels of FIG. 2.

Referring to FIG. 2 and FIG. 3, the display device according to an embodiment may comprise a display panel 10, a driving circuit 20, a scan driving unit 30, and a power supply circuit 50.

The display device 100 of the embodiment may drive a light-emitting element in an active matrix (AM) manner or a passive matrix (PM) manner.

The driving circuit 20 may comprise a data driving unit 21 and a timing controller 22.

The display panel 10 may be formed in a rectangular shape, but is not limited thereto. That is, the display panel 10 may be formed in a circular or oval shape. At least one side of the display panel 10 may be formed to be bent at a predetermined curvature.

The display panel 10 may be divided into a display region DA and a non-display region NDA disposed around the display region DA. The display region DA is a region where pixels PX are formed to display an image. The display panel 10 may comprise data lines (D1 to Dm, m is an integer greater than or equal to 2), scan lines (S1 to Sn, n is an integer greater than or equal to 2) intersecting the data lines D1 to Dm, a high-potential voltage line VDDL to which a high-potential voltage is supplied, a low-potential voltage line VSSL to which a low-potential voltage VSS is supplied, and pixels PX connected to the data lines D1 to Dm and the scan lines S1 to Sn.

Each of the pixels PX may comprise a first subpixel PX1, a second subpixel PX2, and a third subpixel PX3. The first subpixel PX1 may emit a first color light of a first main wavelength, the second subpixel PX2 may emit a second color light of a second main wavelength, and the third subpixel PX3 may emit a third color light of a third main wavelength. The first color light may be red light, the second color light may be green light, and the third color light may be blue light, but is not limited thereto. In addition, although FIG. 2 illustrates that each of the pixels PX comprises three subpixels, it is not limited thereto. That is, each of the pixels PX may comprise four or more subpixels.

Each of the first subpixel PX1, the second subpixel PX2, and the third subpixel PX3 may be connected to at least one of the data lines D1 to Dm, at least one of the scan lines S1 to Sn, and a high-potential voltage line VDDL. The first subpixel PX1 may comprise light-emitting elements LD, a plurality of transistors for supplying current to the light-emitting elements LD, and at least one capacitor Cst, as illustrated in FIG. 3.

Although not illustrated in the drawing, each of the first subpixel PX1, the second subpixel PX2, and the third subpixel PX3 may comprise only one light-emitting element LD and at least one capacitor Cst.

Each of the light-emitting elements LD may be a semiconductor light-emitting diode that comprises a first electrode, a plurality of conductivity type semiconductor layers, and a second electrode. Here, the first electrode may be an anode electrode, and the second electrode may be a cathode electrode, but is not limited thereto.

The light-emitting element LD may be one of a lateral-type light-emitting element, a flip-chip type light-emitting element, and a vertical-type light-emitting element.

The plurality of transistors may comprise a driving transistor DT for supplying current to the light-emitting elements LD, as illustrated in FIG. 3, and a scan transistor ST for supplying a data voltage to a gate electrode of the driving transistor DT. The driving transistor DT may comprise a gate electrode connected to a source electrode of the scan transistor ST, a source electrode connected to a high-potential voltage line VDDL to which a high-potential voltage is applied, and a drain electrode connected to the first electrodes of the light-emitting elements LD. The scan transistor ST may comprise a gate electrode connected to a scan line (Sk, where k is an integer satisfying 1≤k≤n), a source electrode connected to the gate electrode of the driving transistor DT, and a drain electrode connected to a data line (Dj, where j is an integer satisfying 1≤j≤m).

A capacitor Cst is formed between the gate electrode and the source electrode of the driving transistor DT. The storage capacitor Cst charges a difference value between a gate voltage and a source voltage of the driving transistor DT.

The driving transistor DT and the scan transistor ST may be formed as thin film transistors. In addition, in FIG. 3, the driving transistor DT and the scan transistor ST are described mainly as being formed as a P-type metal oxide semiconductor field effect transistor (MOSFET), but the present invention is not limited thereto. The driving transistor DT and the scan transistor ST may be formed as N-type MOSFETs. In this instance, the positions of the source electrode and the drain electrode of each of the driving transistor DT and the scan transistor ST may be changed.

In addition, in FIG. 3, the first subpixel PX1, the second subpixel PX2, and the third subpixel PX3 each comprise 2T1C (2 Transistor-1 capacitor) having one driving transistor DT, one scan transistor ST, and one capacitor Cst, but the present invention is not limited thereto. The first subpixel PX1, the second subpixel PX2, and the third subpixel PX3 each may comprise a plurality of scan transistors ST and a plurality of capacitors Cst.

Since the second subpixel PX2 and the third subpixel PX3 may be expressed by substantially the same circuit diagram as the first subpixel PX1, a detailed description thereof will be omitted.

The driving circuit 20 outputs signals and voltages for driving the display panel 10. To this end, the driving circuit 20 may comprise a data driving unit 21 and a timing controller 22.

The data driving unit 21 receives digital video data DATA and a control signal CS from the timing controller 22. The data driving unit 21 converts the digital video data DATA into analog data voltages according to the control signal CS and supplies the converted data to the data lines D1 to Dm of the display panel 10.

The timing controller 22 receives digital video data DATA and timing signals from a host system. The timing signals may comprise a vertical synchronization signal, a horizontal synchronization signal, a data enable signal, and a dot clock. The host system may be an application processor of a smartphone or tablet PC, a monitor, a system-on-chip of a TV, etc.

The timing controller 22 generates control signals for controlling an operation timing of the data driving unit 21 and the scan driving unit 30. The control signals may comprise a control signal CS for controlling an operation timing of the data driving unit 21 and a scan control signal SCS for controlling an operation timing of the scan driving unit 30.

The driving circuit 20 may be disposed in a non-display region NDA provided on one side of the display panel 10. The driving circuit 20 may be formed as an integrated circuit (IC) and may be mounted on the display panel 10 in a chip on glass (COG) manner, a chip on plastic (COP) manner, or an ultrasonic bonding manner, but the present invention is not limited thereto. For example, the driving circuit 20 may be mounted on a circuit board (not illustrated) other than the display panel 10.

The data driving unit 21 may be mounted on the display panel 10 in a chip on glass (COG) manner, a chip on plastic (COP) manner, or an ultrasonic bonding manner, and the timing controller 22 may be mounted on a circuit board.

The scan driving unit 30 receives a scan control signal SCS from the timing controller 22. The scan driving unit 30 generates scan signals according to the scan control signal SCS and supplies them to the scan lines S1 to Sn of the display panel 10. The scan driving unit 30 may be formed in a non-display region NDA of the display panel 10 and comprise a plurality of transistors. Alternatively, the scan driving unit 30 may be formed as an integrated circuit, in which case it may be mounted on a gate flexible film attached to the other side of the display panel 10.

The circuit board may be attached to pads provided on one side edge of the display panel 10 using an anisotropic conductive film. As a result, lead lines of the circuit board may be electrically connected to the pads. The circuit board may be a flexible film such as a flexible printed circuit board, a printed circuit board, or a chip on film. The circuit board may be bent to a rear side of the display panel 10. Accordingly, one side of the circuit board is attached to one edge of the display panel 10, and the other side is disposed at the rear side of the display panel 10 and may be connected to a system board on which a host system is mounted.

The power supply circuit 50 may generate voltages required for driving the display panel 10 from the main power applied from the system board and supply them to the display panel 10. For example, the power supply circuit 50 may generate a high-potential voltage VDD and a low-potential voltage VSS for driving the light-emitting elements LD of the display panel 10 from the main power and supply them to the high-potential voltage line VDDL and the low-potential voltage line VSSL of the display panel 10. In addition, the power supply circuit 50 may generate and supply driving voltages for driving the driving circuit 20 and the scan driving unit 30 from the main power.

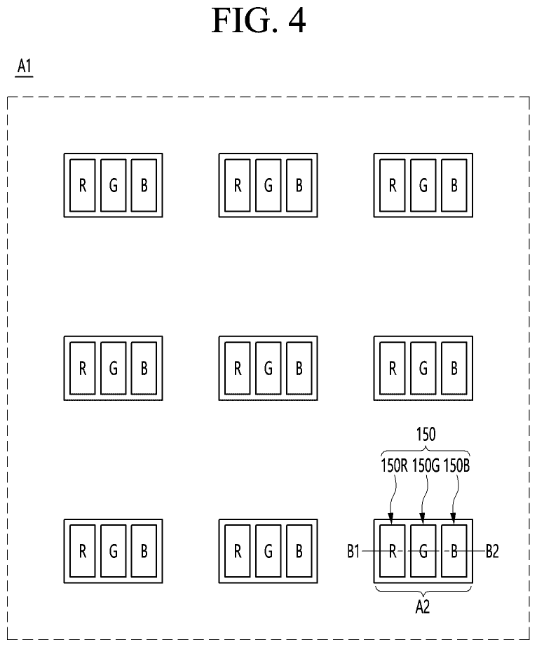

FIG. 4 is an enlarged view of a first panel region in the display device of FIG. 1.

Referring to FIG. 4, the display device 100 of the embodiment may be manufactured by mechanically and electrically connecting a plurality of panel regions, such as the first panel region A1, by tiling.

The first panel region A1 may comprise a plurality of semiconductor light-emitting elements 150 disposed for each unit pixel (PX of FIG. 2).

For example, the unit pixel PX may comprise a first subpixel PX1, a second subpixel PX2, and a third subpixel PX3. For example, a plurality of red semiconductor light-emitting elements 150R may be disposed in the first subpixel PX1, a plurality of green semiconductor light-emitting elements 150G may be disposed in the second subpixel PX2, and a plurality of blue semiconductor light-emitting elements 150B may be disposed in the third subpixel PX3. The unit pixel PX may further comprise a fourth subpixel in which no semiconductor light-emitting elements are disposed, but is not limited thereto.

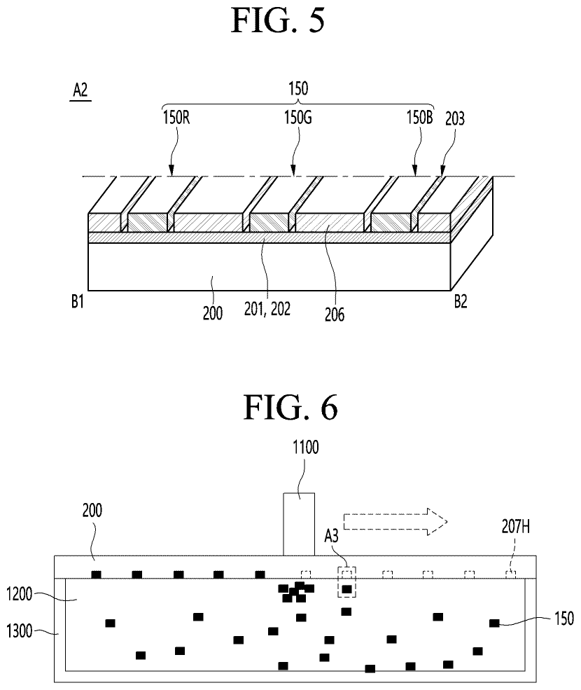

FIG. 5 is an enlarged view of a region A2 of FIG. 4.

Referring to FIG. 5, the display device 100 of the embodiment may comprise a substrate 200, assembly wirings 201 and 202, an insulating layer 206, and a plurality of semiconductor light-emitting elements 150. More components may be included than these.

The assembly wirings may comprise a first assembly wiring 201 and a second assembly wiring 202 that are spaced apart from each other. The first assembly wiring 201 and the second assembly wiring 202 may be provided to generate a DEP force for assembling the semiconductor light-emitting element 150. For example, the semiconductor light-emitting element 150 may be one of a lateral-type semiconductor light-emitting element, a flip-chip type semiconductor light-emitting element, and a vertical-type semiconductor light-emitting element.

The semiconductor light-emitting element 150 may comprise, but is not limited to, a red semiconductor light-emitting element 150, a green semiconductor light-emitting element 150G, and a blue semiconductor light-emitting element 150B to form a unit pixel, respectively, and may also comprise a red phosphor and a green phosphor to implement red and green, respectively.

The substrate 200 may be a support member that supports components disposed on the substrate 200 or a protective member that protects the components.

The substrate 200 may be a rigid substrate or a flexible substrate. The substrate 200 may be formed of sapphire, glass, silicon, or polyimide. In addition, the substrate 200 may comprise a flexible material such as polyethylene naphthalate (PEN), polyethylene terephthalate (PET), etc. In addition, the substrate 200 may be a transparent material, but is not limited thereto. The substrate 200 may function as a support substrate in a display panel, and may also function as an assembly substrate during self-assembly of a light-emitting element.

The substrate 200 may be a backplane equipped with circuits, such as transistors ST and DT, capacitors Cst, and signal wiring, within the subpixels PX1, PX2, and PX3 illustrated in FIGS. 2 and 3, but is not limited thereto. The backplane may be called a circuit board, a driving substrate, a support substrate, an insulating substrate, a protective substrate, etc.

The insulating layer 206 may comprise an insulating and flexible organic material such as polyimide, PAC, PEN, PET, polymer, or an inorganic material such as silicon oxide (SiO₂) or silicon nitride series (SiNx), and may be formed integrally with the substrate 200 to form a single substrate.

The insulating layer 206 may be a conductive adhesive layer having adhesiveness and conductivity, and the conductive adhesive layer may have flexibility to enable a flexible function of the display device. For example, the insulating layer 206 may be a conductive adhesive layer such as an anisotropic conductive film (ACF) or an anisotropic conductive medium, a solution containing conductive particles, etc. The conductive adhesive layer may be a layer that is electrically conductive in a vertical direction relative to the thickness, or electrically insulating in a horizontal direction relative to the thickness.

The insulating layer 206 may comprise an assembly hole 203 for inserting a semiconductor light-emitting element 150. Therefore, when self-assembling, the semiconductor light-emitting element 150 may be easily inserted into the assembly hole 203 of the insulating layer 206. The assembly hole 203 may be called an insertion hole, a fixing hole, an alignment hole, etc. The assembly hole 203 may also be called a hole.

The assembly hole 203 may be called a hole, a groove, a recess, a pocket, etc.

The assembly hole 203 may be different depending on the shape of the semiconductor light-emitting element 150. For example, the red semiconductor light-emitting element, the green semiconductor light-emitting element, and the blue semiconductor light-emitting element each have different shapes, and an assembly hole 203 having a shape corresponding to each shape of these semiconductor light-emitting elements may be provided. For example, the assembly hole 203 may comprise a first assembly hole for assembling the red semiconductor light-emitting element, a second assembly hole for assembling the green semiconductor light-emitting element, and a third assembly hole for assembling the blue semiconductor light-emitting element. For example, the red semiconductor light-emitting element may have a circular shape, the green semiconductor light-emitting element may have a first oval shape having a first minor axis and a first major axis, and the blue semiconductor light-emitting element may have a second oval shape having a second minor axis and a second major axis, but is not limited thereto. The second major axis of the oval shape of the blue semiconductor light-emitting element may be longer than the first major axis of the oval shape of the green semiconductor light-emitting element, and the second minor axis of the oval shape of the blue semiconductor light-emitting element may be shorter than the first minor axis of the oval shape of the green semiconductor light-emitting element.

Meanwhile, the method of mounting the semiconductor light-emitting element 150 on the substrate 200 may comprise, for example, a self-assembly method (FIG. 6) and a transfer method.

FIG. 6 is a diagram illustrating an example in which a light-emitting element according to an embodiment is assembled on a substrate by a self-assembly method.

Based on FIG. 6, an example of assembling a semiconductor light-emitting element according to an embodiment onto a display panel by a self-assembly method using an electromagnetic field will be described.

An assembly substrate 200 described below may also function as a panel substrate 200a in a display device after assembling the light-emitting element, but the embodiment is not limited thereto.

Referring to FIG. 6, the semiconductor light-emitting element 150 may be put into a chamber 1300 filled with a fluid 1200, and the semiconductor light-emitting element 150 may be moved to the assembly substrate 200 by a magnetic field generated from an assembly device 1100. At this time, the semiconductor light-emitting element 150 adjacent to the assembly hole 207H of the assembly substrate 200 may be assembled into the assembly hole 207H by the DEP force caused by the electric field of the assembly wirings. The fluid 1200 may be water such as ultrapure water, but is not limited thereto. The chamber 1300 may be called a tank, a container, a vessel, etc.

After the semiconductor light-emitting element 150 is put into the chamber 1300, the assembly substrate 200 may be disposed on the chamber 1300. According to an embodiment, the assembly substrate 200 may also be put into the chamber 1300.

The semiconductor light-emitting element 150 may be implemented as a vertical-type semiconductor light-emitting element as illustrated, but is not limited thereto, and a lateral-type light-emitting element may be employed.

The semiconductor light-emitting element 150 may comprise a magnetic layer (not illustrated) having a magnetic substance. The magnetic layer may comprise a metal having magnetism, such as nickel (Ni). Since the semiconductor light-emitting element 150 put into the fluid 1200 comprises the magnetic layer, it may move to the assembly substrate 200 by a magnetic field generated from the assembly device 1100. The magnetic layer may be disposed on an upper side, a lower side, or both sides of the light-emitting element.

The semiconductor light-emitting element 150 may comprise a passivation layer 156 surrounding an upper surface and side surfaces thereof. The passivation layer 156 may be formed by using an inorganic insulator, such as silica or alumina, through PECVD, LPCVD, sputtering deposition, etc. In addition, the passivation layer 156 may be formed by a method of spin coating an organic material such as a photoresist or a polymer material.

The semiconductor light-emitting element 150 may comprise a first conductivity type semiconductor layer 152a, a second conductivity type semiconductor layer 152c, and an active layer 152b disposed therebetween. The first conductivity type semiconductor layer 152a may be an n-type semiconductor layer, and the second conductivity type semiconductor layer 152c may be a p-type semiconductor layer, but is not limited thereto. The first conductivity type semiconductor layer 152a, the second conductivity type semiconductor layer 152c, and the active layer 152b disposed therebetween may constitute a light-emitting portion 152. The light-emitting portion 152 may be called a light-emitting layer, a light-emitting region, etc.

A first electrode (layer) 154a may be disposed under the first conductivity type semiconductor layer 152a, and a second electrode (layer) 154b may be disposed on the second conductivity type semiconductor layer 152c. To this end, a part of the first conductivity type semiconductor layer 152a or the second conductivity type semiconductor layer 152c may be exposed to the outside. Accordingly, after the semiconductor light-emitting element 150 is assembled on the assembly substrate 200, a part of the passivation layer 156 may be etched in the manufacturing process of the display device.

The first electrode 154a may comprise at least one or more layer. For example, the first electrode 154a may comprise an ohmic layer, a reflective layer, a magnetic layer, a conductive layer, an anti-oxidation layer, an adhesive layer, etc. The ohmic layer may comprise Au, AuBe, etc. The reflective layer may comprise Al, Ag, etc. The magnetic layer may comprise Ni, Co, etc. The conductive layer may comprise Cu, etc. The anti-oxidation layer may comprise Mo, etc. The adhesive layer may comprise Cr, Ti, etc.

The second electrode 154b may comprise a transparent conductive layer. For example, the second electrode 154b may comprise ITO, IZO, etc.

The assembly substrate 200 may comprise a pair of first assembly wirings 201 and second assembly wirings 202 corresponding to each of the semiconductor light-emitting elements 150 to be assembled. Each of the first assembly wiring 201 and the second assembly wiring 202 may be formed by laminating a single metal or a metal alloy, a metal oxide, etc. in multiple layers. For example, each of the first assembly wiring 201 and the second assembly wiring 202 may be formed by comprising at least one of Cu, Ag, Ni, Cr, Ti, Al, Rh, Pd, Ir, Ru, Mg, Zn, Pt, Au, Hf, but is not limited thereto.

The first assembly wiring 201 and the second assembly wiring 202 form an electric field when an AC voltage is applied, and the semiconductor light-emitting element 150 put into the assembly hole 207H may be fixed by the DEP force caused by the electric field. A gap between the first assembly wiring 201 and the second assembly wiring 202 may be smaller than a width of the semiconductor light-emitting element 150 and a width of the assembly hole 207H, and the assembly position of the semiconductor light-emitting element 150 may be fixed more precisely using the electric field.

An insulating layer 215 may be formed on the first assembly wiring 201 and the second assembly wiring 202 to protect the first assembly wiring 201 and the second assembly wiring 202 from the fluid 1200 and prevent leakage of current flowing in the first assembly wiring 201 and the second assembly wiring 202. For example, the insulating layer 215 may be formed of a single layer or multiple layers of an inorganic insulator such as silica or alumina, or an organic insulator. The insulating layer 215 may have a minimum thickness to prevent damage to the first assembly wiring 201 and the second assembly wiring 202 during assembly of the semiconductor light-emitting element 150, and may have a maximum thickness to stably assemble the semiconductor light-emitting element 150.

A partition wall 207 may be formed on an upper part of the insulating layer 215. A part of the partition wall 207 may be positioned on an upper part of the first assembly wiring 201 and the second assembly wiring 202, and the remaining regions may be positioned on the upper part of the assembly substrate 200.

Meanwhile, when manufacturing the assembly substrate 200, a part of the partition wall formed on the upper part of the insulating layer 215 may be removed, thereby forming an assembly hole 207H in which each of the semiconductor light-emitting elements 150 is coupled and assembled to the assembly substrate 200.

An assembly hole 207H may be formed on the assembly substrate 200, into which semiconductor light-emitting elements 150 are combined, and a surface on which the assembly hole 207H is formed may be in contact with a fluid 1200. The assembly hole 207H may guide an accurate assembly position of the semiconductor light-emitting element 150.

Meanwhile, the assembly hole 207H may have a shape and size corresponding to the shape of the semiconductor light-emitting element 150 to be assembled at the corresponding position. Accordingly, it is possible to prevent another semiconductor light-emitting element from being assembled in the assembly hole 207H or a plurality of semiconductor light-emitting elements from being assembled.

Referring back to FIG. 6, after the assembly substrate 200 is disposed in the chamber 1300, the assembly device 1100 applying a magnetic field may move along the assembly substrate 200. The assembly device 1100 may be a permanent magnet or an electromagnet.

The assembly device 1100 may move in contact with the assembly substrate 200 to maximize a region affected by the magnetic field within the fluid 1200. Depending on the embodiment, the assembly device 1100 may comprise a plurality of magnetic substances or may comprise magnetic substances of a size corresponding to the assembly substrate 200. In this instance, the movement distance of the assembly device 1100 may be limited within a predetermined range.

The semiconductor light-emitting element 150 within the chamber 1300 may move toward the assembly device 1100 and the assembly substrate 200 by the magnetic field generated by the assembly device 1100.

The semiconductor light-emitting element 150 may be fixed by entering the assembly hole 207H by the DEP force formed by the electric field between the assembly wirings 201 and 202 while moving toward the assembly device 1100.

Specifically, the first and second assembly wirings 201 and 202 may form an electric field by an AC power source, and the DEP force may be formed between the assembly wirings 201 and 202 by this electric field. The semiconductor light-emitting element 150 may be fixed to the assembly hole 207h on the assembly substrate 200 by the DEP force.

At this time, a predetermined solder layer (not illustrated) may be formed between the semiconductor light-emitting element 150 assembled on the assembly hole 207H of the assembly substrate 200 and the assembly wirings 201 and 202, thereby improving the bonding strength of the semiconductor light-emitting element 150.

In addition, a molding layer (not illustrated) may be formed in the assembly hole 207H of the assembly substrate 200 after assembly. The molding layer may be a transparent resin or a resin containing a reflective material or a scattering material.

Since the time required for each semiconductor light-emitting element to be assembled on the substrate may be drastically shortened by the self-assembly method using the electromagnetic field described above, a large-area high-pixel display may be implemented more quickly and economically.

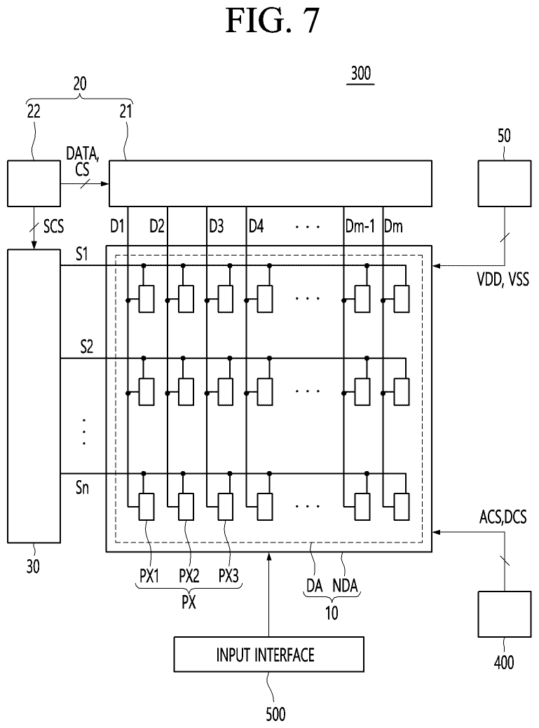

Hereinafter, various embodiments for solving the above-described problem will be described with reference to FIGS. 7 to 19. Any description omitted below may be easily understood from the description described above with respect to FIGS. 1 to 6 and the corresponding drawings.

FIG. 7 is a circuit diagram illustrating a display device according to an embodiment.

Referring to FIG. 7, the display device 300 according to the embodiment may comprise a display panel 10, a driving circuit 20, a scan driving unit 30, a power supply circuit 50, and a signal supply unit 400. The driving circuit 20 may comprise a data driving unit 21 and a timing controller 22.

The display panel 10, the driving circuit 20, the scan driving unit 30, and the power supply circuit 50 have been described above, so that a detailed description thereof will be omitted.

The display panel 10 may comprise a display region DA. The display panel 10 may comprise a non-display region NDA. The non-display region NDA may be a region excluding the display region DA.

As an example, the display region DA and the non-display region NDA may be defined on the same surface. For example, the non-display region NDA may surround the display region DA on the same surface together with the display region DA, but is not limited thereto.

As another example, although not illustrated in the drawing, the display region DA and the non-display region NDA may be defined on different surfaces. For example, the display region DA may be defined on an upper surface of the substrate, and the non-display region NDA may be defined on a lower surface of the substrate. For example, the non-display region NDA may be defined on an entire region or a part of the lower surface of the substrate.

Meanwhile, although the drawing illustrates that the display region DA and the non-display region NDA are divided, the display region DA and the non-display region NDA may not be divided. That is, only the display region DA may exist on the upper surface of the substrate, and the non-display region NDA may not exist. In other words, the entire region of the upper surface of the substrate may be the display region DA where the image is displayed, and a bezel area, which is the non-display region NDA, may not exist.

The display region DA is a region that displays an image, and may comprise a plurality of pixels PX. Each of the plurality of pixels PX may display a full color image. The plurality of pixels PX may each comprise a plurality of subpixels PX1, PX2, and PX3. For example, the plurality of pixels PX may each comprise a first subpixel PX1, a second subpixel PX2, and a third subpixel PX3.

The subpixels PX1, PX2, and PX3 may be connected to the scan driving unit 30, the data driving unit 21, the power supply circuit 50, and the signal supply unit 400, respectively. For example, the scan driving unit may supply scan signals to the subpixels PX1, PX2, and PX3 through the scan lines S1 to Sn for each pixel line. The pixel line may mean a virtual line along a horizontal direction. That is, the plurality of subpixels PX1, PX2, and PX3 arranged along the horizontal direction may constitute one pixel line. For example, a first scan signal may be supplied to a plurality of subpixels PX1, PX2, and PX3 on a first pixel line through a first scan line S1, and then a second scan signal may be supplied to a plurality of subpixels PX1, PX2, and PX3 on a second pixel line through a second scan line S2. In this manner, scan signals may be sequentially supplied to a plurality of subpixels PX1, PX2, and PX3 on the remaining pixel lines.

For example, the data driving unit 21 may supply a data signal (or voltage) to the subpixels PX1, PX2, and PX3. For example, the power supply circuit 50 may supply a high-potential voltage VDD and a low-potential voltage VSS to the subpixels PX1, PX2, and PX3. For example, the signal supply unit 400 may selectively supply an AC signal ACS or a DC signal DCS to the subpixels PX1, PX2, and PX3.

When self-assembling, the signal supply unit 400 may supply an AC signal ACS to the first assembly wiring and the second assembly wiring of each of the plurality of subpixels PX1, PX2, and PX3, so that a DEP force may be formed on the first assembly wiring and the second assembly wiring. By the DEP force, a semiconductor light-emitting element flowing in a fluid may be assembled on the first assembly wiring and the second assembly wiring.

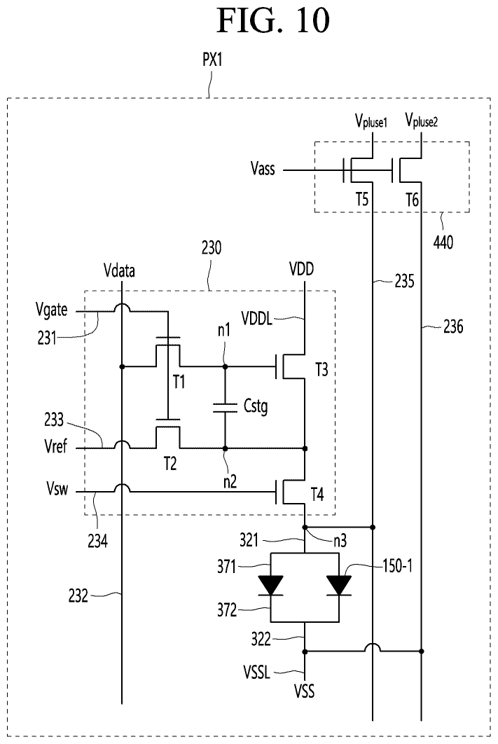

When aging, the signal supply unit 400 may supply a DC signal DCS to the first assembly wiring and the second assembly wiring of each of the plurality of subpixels PX1, PX2, and PX3, so that the semiconductor light-emitting element of each of the plurality of subpixels PX1, PX2, and PX3 may be aged, so that the luminance deviation between the plurality of subpixels PX1, PX2, and PX3 may be reduced or eliminated, thereby improving the image quality. A reference voltage Vref may be stored in a capacitor (Cstg of FIG. 10).

When the signal supply unit 400 emits light, the AC signal ACS and the DC signal DCS may be not supplied to the plurality of subpixels PX1, PX2, and PX3, so that the plurality of subpixels PX1, PX2, and PX3 may each implement the desired luminance and color to display full-color images without being interfered by the respective AC signal ACS and DC signal DCS.

The display device 300 according to the embodiment may comprise an input interface 500.

The input interface 500 may receive an aging activation command. When the display device 300 according to the embodiment is shipped and the user displays the image for a long time, the image quality may degrade. In this instance, when the aging activation command is input through the input interface 500, the DC signal DCS may be supplied from the signal supply unit 400 to the subpixels PX1, PX2, and PX3 in response to the aging activation command. Accordingly, the image quality can be improved by aging the subpixels PX1, PX2, and PX3 by the DC signal DCS. Here, the degradation of the image quality may mean that a difference in luminance occurs between the plurality of pixels PX or between the plurality of subpixels PX1, PX2, and PX3. The aging may mean reducing or eliminating the luminance deviation between the plurality of subpixels PX1, PX2, and PX3 by supplying the same DC signal DCS to the plurality of subpixels PX1, PX2, and PX3.

The input interface 500 may receive a predetermined aging activation command through communication with a remote control device (not illustrated) such as a remote controller. In this instance, the controller, which is not illustrated, or timing controller 22 may generate a control signal corresponding to the aging activation command and control the signal supply unit 400 to supply the DC signal DCS to the subpixels PX1, PX2, and PX3 in response to the control signal.

Meanwhile, a pointer (not illustrated) may be displayed on the screen of the display, and the pointer on the screen of the display may be moved in response to the movement of the remote control device in the 3D space. In this instance, the remote control device may be called a space remote controller or a 3D pointing device. Accordingly, when an item (or icon) corresponding to an aging activation command is displayed on the screen of the display, the pointer may be moved to the position of the corresponding item in response to the movement of the remote control device in the 3D space. When a specific button of the remote control device is pressed while the pointer is moved to the position of the corresponding item, the corresponding item may be clicked by the pointer, and an aging operation may be performed in response to the corresponding aging activation command.

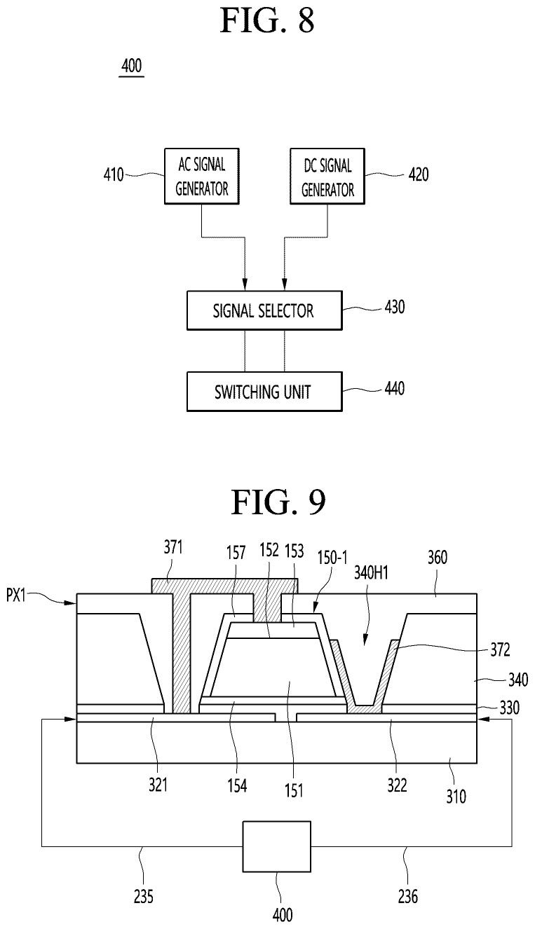

FIG. 8 is a block diagram illustrating a signal supply unit of an embodiment.

Referring to FIG. 8, the signal supply unit 400 may comprise an AC signal generator 410, a DC signal generator 420, a signal selector 430, and a switching unit 440.

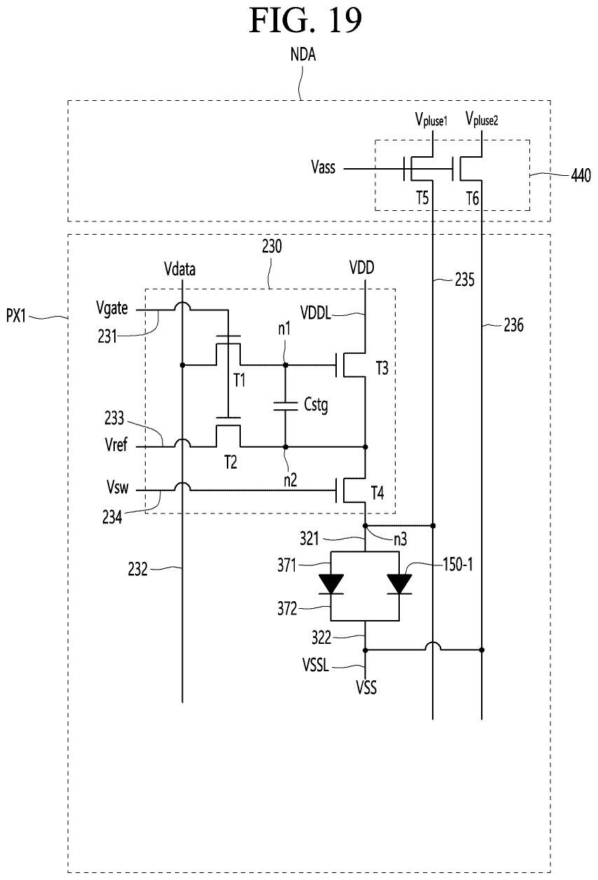

For example, the AC signal generator 410, the DC signal generator 420, and the signal selector 430 may be provided on the non-display region NDA. For example, the signal selector 430 may be provided in each of the plurality of subpixels PX1, PX2, and PX3 as illustrated in FIG. 10, or may be provided on the non-display region NDA as illustrated in FIG. 19. A plurality of switching units 440 or one switching unit 440 may be provided on the non-display region NDA. When a plurality of switching units 440 are provided, they may be provided as many as the number of subpixels PX1, PX2, and PX3 arranged in the horizontal direction, but is not limited thereto. When one switching unit 440 is provided, two signal lines of one switching unit 440 may be connected to the first assembly wiring 321 and the second assembly wiring 322 of each of the plurality of subpixels PX1, PX2, and PX3.

The AC signal generator 410 may generate an AC signal ACS. The AC signal generator 410 may generate the AC signal ACS based on a supply voltage output from the power supply unit (not illustrated). As will be described later, the AC signal ACS may be used to form a DEP force for assembling a semiconductor light-emitting element on a substrate during self-assembly.

The DC signal generator 420 may generate a DC signal DCS. The DC signal generator 420 may generate the DC signal DCS based on a supply voltage output from the power supply unit. As will be described later, the DC signal DCS may be used to supply a semiconductor light-emitting element of each of the plurality of subpixels PX1, PX2, and PX3 to reduce or eliminate the luminance deviation between the plurality of subpixels PX1, PX2, and PX3.

The signal selector 430 may selectively output an AC signal ACS or a DC signal DCS. The signal selector 430 may selectively output the AC signal ACS or the DC signal DCS according to a control signal provided from the control unit (not illustrated) or the timing controller.

For example, during self-assembly, the control unit or the timing controller may supply a control signal having “01” to the signal selector 430, and the signal selector 430 may select and output the AC signal ACS among the AC signal ACS and the DC signal DCS according to the control signal having “01”. For example, during aging, the control unit or the timing controller may supply a control signal having “11” to the signal selector 430, and the signal selector 430 may select and output the DC signal DCS among the AC signal ACS and the DC signal DCS according to the control signal having “11”.

For example, when emitting light, the signal control unit or the timing controller may supply a control signal having “00” to the signal selector 430, and the signal selector 430 may not output both the AC signal ACS and the DC signal DCS according to the control signal having “00.” Or, when emitting light, the control signal having “00” may be supplied to the AC signal generator 410 and the DC signal generator 420, so as to block the output of the AC signal ACS from the AC signal generator 410 and the output of the DC signal DCS from the DC signal generator 420.

The switching unit 440 may control supply of an output signal of the signal selector 430. The switching unit 440 may supply the output signal of the signal selector 430 or block the supply thereof. The switching unit 440 may control the supply of the output signal of the signal selector 430 according to the control signal provided from the control unit (not illustrated) or the timing controller.

For example, during self-assembly, the control unit or timing controller may supply a control signal having “01” to the switching unit 440, and the switching unit 440 may supply an output signal of the signal selector 430, i.e., an AC signal ACS, to each of the plurality of subpixels PX1, PX2, and PX3 according to the control signal having “01.” By this AC signal ACS, a DEP force may be formed in each of the plurality of subpixels PX1, PX2, and PX3, and by the DEP force, a semiconductor light-emitting element flowing in a fluid may be assembled in the corresponding subpixels PX1, PX2, and PX3.

For example, during aging, the control unit or the timing controller may supply a control signal having “11” to the switching unit 440, and the switching unit 440 may supply an output signal of the signal selector 430, i.e., a DC signal DCS, to each of the plurality of subpixels PX1, PX2, and PX3 according to the control signal having “11.” By the DC signal DCS, the semiconductor light-emitting elements of each of the plurality of subpixels PX1, PX2, and PX3 may be aged, so that the luminance deviation between the plurality of subpixels PX1, PX2, and PX3 may be reduced or eliminated, thereby improving the image quality.

During light-emitting, the control unit or the timing controller may supply a control signal having “00” to the switching unit 440, and the switching unit 440 may block the supply of the output signal of the signal selector 430 according to the control signal having “00.” Accordingly, the semiconductor light-emitting elements of each of the plurality of subpixels PX1, PX2, and PX3 may stably emit light without interference of the output signal of the signal selector 430, so that a full-color image may be displayed.

Meanwhile, the switching unit 440 may comprise a fifth transistor T5 and a sixth transistor T6, as illustrated in FIG. 10 or FIG. 19. The fifth transistor T5 and the sixth transistor T6 may be formed by the same semiconductor process as the first transistor T1, the second transistor T2, the third transistor T3, and the fourth transistor T4, but are not limited thereto.

The fifth transistor T5 may switch supply of an output signal to the first assembly wiring illustrated in FIG. 9, that is, a first voltage Vpulse1 of the AC signal ACS or the DC signal DCS. The sixth transistor T6 may switch supply of an output signal to the second assembly wiring 322, that is, a second voltage Vpulse2 of the AC signal ACS or the DC signal DCS.

For example, in the case of the AC signal ACS, the first voltage Vpulse1 and the second voltage Vpulse2 may have opposite polarities and be periodically inverted. For example, when the first voltage Vpulse1 is a positive voltage, the second voltage Vpulse2 may have a negative voltage. For example, when the first voltage Vpulse1 is a negative voltage, the second voltage Vpulse2 may have a positive voltage. The first voltage Vpulse1 may periodically have a negative voltage and a positive voltage, and the second voltage Vpulse2 may periodically have a positive voltage and a negative voltage.

For example, in the case of a DC signal DCS, one of the first voltage Vpulse1 and the second voltage Vpulse2 may have a high level and the other may have a low level. For example, the first voltage Vpulse1 may have a high level and the second voltage Vpulse2 may have a low level, but is not limited thereto.

For example, the fifth transistor T5 and the sixth transistor T6 may be turned on or off by a switching control signal Vass. Therefore, the fifth transistor T5 and the sixth transistor T6 may be turned on or off simultaneously by the switching control signal Vass.

In the embodiment, the fifth transistor T5 and the sixth transistor T6 may be N-type transistors, but is not limited thereto. For example, the fifth transistor T5 and the sixth transistor T6 may be turned on by the switching control signal Vass having a high level. For example, the fifth transistor T5 and the sixth transistor T6 may be turned off by the switching control signal Vass having a low level.

The fifth transistor T5 and the sixth transistor T6 may be turned on in response to the switching control signal Vass in a high state during self-assembly. In this instance, the first voltage Vpulse1 of the AC signal ACS output from the signal selector 430 may be supplied to the first assembly wiring, and the second voltage Vpulse2 of the AC signal ACS may be supplied to the second assembly wiring 322. Accordingly, a DEP force may be formed on the first assembly wiring and the second assembly wiring 322.

The fifth transistor T5 and the sixth transistor T6 may be turned on in response to the switching control signal Vass in a high state during aging. In this instance, the first voltage Vpulse1 of the DC signal DCS output from the signal selector 430 may be supplied to the first assembly wiring of each of the plurality of subpixels PX1, PX2, and PX3, and the second voltage Vpulse2 of the DC signal DCS may be supplied to the second assembly wiring 322 of each of the plurality of subpixels PX1, PX2, and PX3. Accordingly, the semiconductor light-emitting element 150-1 of each of the plurality of subpixels PX1, PX2, and PX3 may be aged by the DC voltages supplied to the first assembly wiring and the second assembly wiring 322, so that the luminance deviation between the plurality of subpixels PX1, PX2, and PX3 may be reduced or eliminated.

The fifth transistor T5 and the sixth transistor T6 may be turned off in response to the switching control signal Vass in a low state during light-emitting. In this instance, even if the AC signal ACS or the DC signal DCS is output from the signal selector 430, it may be not supplied to the first assembly wiring and the second assembly wiring 322 of each of the plurality of subpixels PX1, PX2, and PX3.

FIG. 9 illustrates a connection relationship between a first subpixel and a signal supply unit. FIG. 9 illustrates a first subpixel PX1 as a representative among a plurality of subpixels PX1, PX2, and PX3 illustrated in FIG. 7, but other subpixels PX2 and PX3 may have the same structure as the first subpixel PX1, except for the semiconductor light-emitting element 150-1. For example, the first subpixel PX1 may comprise a first semiconductor light-emitting element 150-1 that emits a first color light, the second subpixel PX2 may comprise a second semiconductor light-emitting element that emits a second color light, and the third subpixel PX3 may comprise a third semiconductor light-emitting element that emits a third color light. For example, the first color light may comprise red light, the second color light may comprise green light, and the third color light may comprise blue light.

Hereinafter, the first subpixel PX1 and the subpixel may be used interchangeably.

Referring to FIG. 9, the first subpixel PX1 may comprise a substrate 310, a first assembly wiring 321, a second assembly wiring 322, a first insulating layer 330, a partition wall 340, a semiconductor light-emitting element 150-1, a second insulating layer 360, a first electrode wiring 371, and a second electrode wiring 372. The first subpixel PX1 may comprise more components than these, but is not limited thereto.

The subpixel circuit 230 and the switching unit 440 illustrated in FIG. 10 may be provided on the substrate 310.

The substrate 310 may serve as a supporting member that supports various components of the display device 300.

Although only the first subpixel PX1 is defined on the substrate 310 in the drawing, a plurality of pixels PX comprising the first subpixel PX1, the second subpixel PX2, and the third subpixel PX3, as well as the second subpixel PX2 and the third subpixel PX3, may be defined on the substrate 310.

The first assembly wiring 321 and the second assembly wiring 322 may be disposed on the substrate 310. The first assembly wiring 321 and the second assembly wiring 322 may be spaced apart from each other in the first subpixel PX1. Although the drawing illustrates that the first assembly wiring 321 and the second assembly wiring 322 are disposed on the same layer, they may be disposed on different layers.

The first insulating layer 330 may be disposed on the first assembly wiring 321 and the second assembly wiring 322. The first insulating layer 330 may be formed of an inorganic material such as SiOx, but is not limited thereto. The first insulating layer 330 may insulate the first assembly wiring 321 and the second assembly wiring 322. The first insulating layer 330 may prevent the first assembly wiring 321 and the second assembly wiring 322 from being corroded by a fluid during self-assembly. The first insulating layer 330 may have a predetermined permittivity and may contribute to the formation of a DEP force.

The partition wall 340 may have an assembly hole 340H1. For example, an organic film may be formed on the first insulating layer 330, and may be etched to a size smaller than the first subpixel PX1 using an etching process to form an assembly hole 340H1. The organic film may be etched until the first insulating layer 330 is exposed. The partition wall 340 may be formed of an organic material, but is not limited thereto.

Although the partition wall 340 is illustrated in the drawing, the partition wall 340 may be omitted. That is, after the partition wall 340 having the assembly hole 340H1 is formed to assemble the semiconductor light-emitting element 150-1, the semiconductor light-emitting element 150-1 may be assembled to the first subpixel PX1 by self-assembly. Thereafter, the partition wall 340 may be removed through an ashing process. In this instance, the portion where the partition wall 340 is removed in the drawing may be filled with the second insulating layer 360.

The semiconductor light-emitting element 150-1 may be assembled into the assembly hole 340H1 using a self-assembly method. The self-assembly method may be a method of assembling the semiconductor light-emitting element 150-1 in the fluid onto the first subpixel PX1 using a magnetic field and an electric field (or DEP force). During self-assembly, the semiconductor light-emitting element 150-1 in the fluid may be moved in a rotational or linear direction by a magnetic field formed by a magnet and positioned on the substrate 310. At the same time, a DEP force may be formed on the first assembly wiring 321 and the second assembly wiring 322 by an AC signal ACS supplied from the signal supply unit 400, and the semiconductor light-emitting element 150-1 positioned on the first subpixel PX1 may be assembled into the assembly hole 340H1 by the DEP force.

The second insulating layer 360 may be disposed on the partition wall 340 and the semiconductor light-emitting element 150-1. The second insulating layer 360 may be used as a protective layer that may protect the semiconductor light-emitting element 150-1 from external foreign substances or impact. The second insulating layer 360 may be formed of an organic material, but is not limited thereto. The second insulating layer 360 may be formed on the partition wall 340 and the semiconductor light-emitting element 150-1 using a deposition process, a printing process, or a film attachment process.

The first assembly wiring 321 and a first side of the semiconductor light-emitting element 150-1 may be connected by the first electrode wiring 371, and the second assembly wiring 322 and a second side of the semiconductor light-emitting element 150-1 may be connected by the second electrode wiring 372. The first electrode wiring 371 may be called a first connection electrode, and the second electrode wiring 372 may be called a second connection electrode.

The first electrode wiring 371 may be in contact with the second conductive semiconductor light-emitting element 150-1 of the semiconductor light-emitting element 150-1. When a second electrode such as ITO is formed on the second conductivity type semiconductor layer, the first electrode wiring 371 may be in contact with the second electrode. The first electrode wiring 371 may be disposed on the second insulating layer 360. The first electrode wiring 371 may be connected to the first assembly wiring 321 by penetrating one region of the second insulating layer 360, and may be connected to the first side of the semiconductor light-emitting element 150-1 by penetrating another region of the second insulating layer 360.

The semiconductor light-emitting element 150-1 illustrated in the drawing is a vertical-type semiconductor light-emitting element, but a flip-chip type semiconductor light-emitting element or a lateral-type semiconductor light-emitting element may be equally applied.

The semiconductor light-emitting element 150-1 may comprise a first conductivity type semiconductor layer 151, an active layer 152 on the first conductivity type semiconductor layer 151, and a second conductivity type semiconductor layer 153 on the active layer 152. The first conductivity type semiconductor layer 151, the active layer 152, and the second conductivity type semiconductor layer 153 may be formed using a deposition process. The first conductivity type semiconductor layer 151 may comprise an n-type dopant, and the second conductivity type semiconductor layer 153 may comprise a p-type dopant, but is not limited thereto. A light-emitting layer or a light-emitting portion may be formed by the first conductivity type semiconductor layer 151, the active layer 152, and the second conductivity type semiconductor layer 153.

The semiconductor light-emitting element 150-1 may comprise a first electrode 154 under the first conductivity type semiconductor layer 151 and a passivation layer 157 surrounding the light-emitting portion. Although not illustrated, a second electrode may be formed on the second conductivity type semiconductor layer. The second electrode may be made of a transparent conductive material such as ITO for light transmission.

The second electrode wiring 372 may be in contact with the first electrode 154 of the semiconductor light-emitting element 150-1. The second electrode wiring 372 may be in contact with a side surface of the first electrode 154 of the semiconductor light-emitting element 150-1. The second electrode wiring 372 may be in contact with a side surface of the passivation layer of the semiconductor light-emitting element 150-1 and an inner surface of the partition wall 340 and may be in contact with an upper surface of the second assembly wiring 322.

The second electrode wiring 372 may be formed before the second insulating layer 360 is formed, and the first electrode wiring 371 may be formed after the second insulating layer 360 is formed, but is not limited thereto. Although not illustrated, the first electrode wiring 371 and the second electrode wiring 372 may be disposed on the second insulating layer 360. The first electrode wiring 371 and the second electrode wiring 372 may be spaced apart from each other on the second insulating layer 360. In this instance, the first electrode wiring 371 may penetrate two regions of the second insulating layer 360 and be connected to the first assembly wiring 321 and the first side of the semiconductor light-emitting element 150-1. The second electrode wiring 372 may penetrate the second insulating layer 360 and be connected to the second assembly wiring 322.

Meanwhile, a fifth signal line 235 and a sixth signal line 236 of the signal supply unit 400 may be connected to the first assembly wiring 321 and the second assembly wiring 322, respectively. Accordingly, the AC signal ACS or the DC signal DCS output from the signal supply unit 400 may be supplied to the semiconductor light-emitting element 150-1 through the first assembly wiring 321 and the second assembly wiring 322.

The signal supply unit 400 may be continuously connected to the first assembly wiring 321 and the second assembly wiring 322 not only before or after the self-assembly of the semiconductor light-emitting element 150-1 but also while being used by the customer.

The signal supply unit 400 may be connected to the first assembly wiring 321 and the second assembly wiring 322 even before the self-assembly. In this instance, a DEP force may be formed on the first assembly wiring 321 and the second assembly wiring 322 by the AC signal ACS output from the signal supply unit 400, and the semiconductor light-emitting element 150-1 positioned on the first subpixel PX1 may be assembled into the assembly hole 340H1 by the DEP force.

Thereafter, the second insulating layer 360, the first electrode wiring 371, and the second electrode wiring 372 may be formed by the post-process, and then an aging process may be performed. In this instance, the signal supply unit 400 may supply the DC signal DCS to the semiconductor light-emitting element 150-1 through the first assembly wiring 321 and the second assembly wiring 322. The DC signal DCS may be supplied simultaneously to the first subpixel PX1 as well as the subpixels PX1, PX2, and PX3 included in the display region (DA of FIG. 7), so that the subpixels PX1, PX2, and PX3 included in the display region DA may be aged. Accordingly, the luminance deviation between the plurality of subpixels PX1, PX2, and PX3 may be reduced or eliminated, so that the image quality can be improved.

Thereafter, the lighting defect of the subpixels PX1, PX2, and PX3 included in the display region DA may be inspected. To this end, the signal supply unit 400 does not supply any signal to the first assembly wiring 321 and the second assembly wiring 322. At this time, as illustrated in FIG. 7, the scan signal supplied through each of the scan lines S1 to Sn, the data voltage supplied through each of the data lines D1 to Dm, and the driving current generated by the high-potential voltage VDD and the low-potential voltage VSS supplied from the power supply circuit may be supplied to the semiconductor light-emitting element 150-1 through the first assembly wiring 321 and the second assembly wiring 322, so that the semiconductor light-emitting element 150-1 may emit color light having a luminance corresponding to the driving current.

Thereafter, the display device 300 according to the embodiment may be sold to a customer, and the image quality may degrade while the customer is using the display device 300. In this instance, an aging activation command by a customer may be transmitted to the input interface 500 via a remote control device, and a control signal may be generated by a control unit or a timing controller, so that a DC signal DCS output from a signal supply unit 400 by this control signal may be simultaneously supplied to not only the first subpixel PX1 but also the subpixels PX1, PX2, and PX3 included in the display region (DA of FIG. 7). Accordingly, the luminance deviation between the plurality of subpixels PX1, PX2, and PX3 may be reduced or eliminated by the DC signal DCS, so that the image quality can be improved.

FIG. 10 is a circuit diagram illustrating a first subpixel according to the first embodiment. FIG. 10 illustrates the first subpixel PX1 among the plurality of subpixels PX1, PX2, and PX3 illustrated in FIG. 7 as a representative example, but other subpixels PX2 and PX3 may have the same structure as the first subpixel PX1 except for the semiconductor light-emitting element 150-1.

Referring to FIGS. 9 and 10, the first subpixel PX1 according to the first embodiment may comprise a subpixel circuit 230. The first subpixel PX1 according to the first embodiment may comprise at least one or more semiconductor light-emitting element 150-1. Although not illustrated, the second subpixel PX2 or the third subpixel PX3 may also comprise a subpixel circuit 230 having the same structure as the subpixel circuit 230 illustrated in FIG. 10, but is not limited thereto.

The subpixel circuit 230 may generate a driving current for emitting the semiconductor light-emitting element 150-1. The semiconductor light-emitting element 150-1 may emit light by the driving current. At this time, the luminance of the semiconductor light-emitting element 150-1 may vary depending on the size of the driving current. That is, as the size of the driving current increases, the luminance of the semiconductor light-emitting element 150-1 may increase. The luminance may be divided into, for example, 0 gradation to 255 gradation. The size of the luminance may vary depending on the size of the data voltage and/or the potential difference between the low-potential voltage VSS and the high-potential voltage VDD. The driving current may increase as the size of the data voltage increases. The driving current may increase as the potential difference between the low-potential voltage VSS and the high-potential voltage VDD increases. The driving current may increase as the high-potential voltage VDD increases.

In the drawing, the subpixel circuit 230 is illustrated as being connected to the first assembly wiring 321, but may also be connected to the second assembly wiring 322.

When the light-emitting operation is performed, a predetermined driving current may be generated in the subpixel circuit 230, and the driving current may be supplied to the semiconductor light-emitting element 150-1 through the first assembly wiring 321 and the first electrode wiring 371, so that the semiconductor light-emitting element 150-1 may emit light.

In this way, not only the first subpixel PX1, but also the second subpixel PX2 and the third subpixel PX3 may emit light in the semiconductor light-emitting elements of the second subpixel PX2 and the third subpixel PX3, respectively, by the driving current. At this time, the driving currents of the first subpixel PX1, the second subpixel PX2, and the third subpixel PX3 may be different from each other, but is not limited thereto. When the semiconductor light-emitting elements of the first subpixel PX1, the second subpixel PX2, and the third subpixel PX3 each emit light with the same luminance, the driving currents of the first subpixel PX1, the second subpixel PX2, and the third subpixel PX3 may be the same.

The subpixel circuit 230 may comprise a first transistor T1, a second transistor T2, a third transistor T3, and a capacitor Cstg. At least one or more capacitor Cstg may be provided, and may be referred to as a storage, etc. The first transistor T1, the second transistor T2, and the third transistor T3 may be N-type transistors, but are not limited thereto.

The first transistor T1 may serve to select the first subpixel PX1 for light-emitting. For example, as illustrated in FIG. 7, scan signals (Vgate in FIG. 10) supplied through each of the scan lines S1 to Sn may be sequentially supplied to a plurality of subpixels PX1, PX2, and PX3 on a pixel line. Accordingly, a plurality of subpixels PX1, PX2, and PX3 may be sequentially selected for each pixel line by the plurality of scan signals Vgate. That is, the plurality of subpixels PX1, PX2, and PX3 may be activated so that data voltages may be supplied. The scan signal Vgate may also be referred to as a gate signal, a selection signal, a selection control signal, etc.

For example, a first scan signal supplied through a first scan line S1 may be supplied to a plurality of subpixels PX1, PX2, and PX3 on a first pixel line, and a first transistor T1 of a subpixel circuit 230 may be turned on by the first scan signal in each of the plurality of subpixels PX1, PX2, and PX3. By turning on the first transistor T1, data voltages supplied through each of the plurality of data lines D1 to Dm may be supplied to the plurality of subpixels PX1, PX2, and PX3. Subsequently, a second scan signal supplied through the second scan line S2 may be supplied to the plurality of subpixels PX1, PX2, and PX3 on a second pixel line, and the first transistor T1 of the subpixel circuit 230 may be turned on by the second scan signal in each of the plurality of subpixels PX1, PX2, and PX3. By turning on the second transistor T2, data voltages supplied through each of the plurality of data lines D1 to Dm may be supplied to the plurality of subpixels PX1, PX2, and PX3.

In this manner, the remaining scan signals may be supplied to the plurality of subpixels PX1, PX2, and PX3 of each of a third pixel line to a nth pixel line, so that the plurality of subpixels PX1, PX2, and PX3 of each of the third pixel line to the nth pixel line may be sequentially activated.

Referring again to FIG. 10, the first transistor T1 may be connected between the first signal line 231, the second signal line 232, and the first node n1. For example, the first transistor T1 may comprise a gate terminal connected to the first signal line 231, a source terminal connected to the second signal line 232, and a drain terminal connected to the first node n1. The first signal line 231 may be one scan line among the plurality of scan lines S1 to Sn illustrated in FIG. 7, and the second signal line 232 may be one data line among the plurality of data lines D1 to Dm illustrated in FIG. 7.

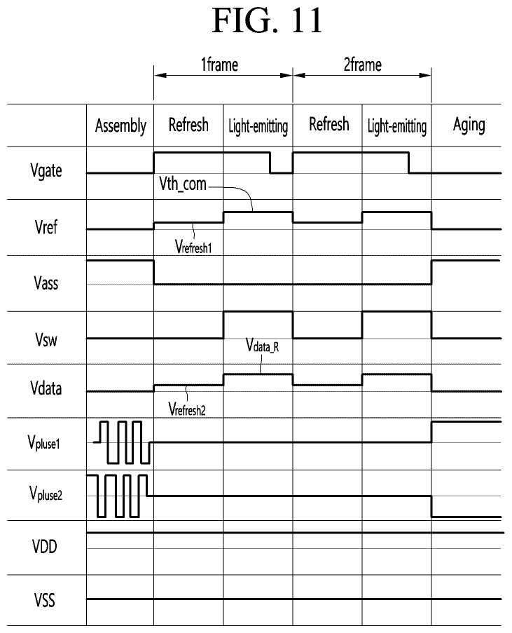

The second transistor T2 may initialize the subpixels PX1, PX2, and PX3 or the subpixel circuit 230, while compensating for the threshold voltage of the third transistor T3. During the light-emitting operation, the reference voltage Vref may be divided into a first section in which a refresh voltage is applied and a second section in which a threshold compensation voltage (Vth_Com in FIG. 11) equal to the threshold voltage of the third transistor T3 is applied to compensate for the deviation of the threshold voltage of the third transistor T3.

To this end, the second transistor T2 may be connected between the first signal line 231, the third signal line 233, and the second node n2. For example, the second transistor T2 may comprise a gate terminal connected to the first signal line 231, a source terminal connected to the third signal line 233, and a drain terminal connected to the second node n2.

When the first transistor T1 and the second transistor T2 are turned on by a gate signal having a high level during the first section, a refresh voltage Vref1 as a reference voltage Vref may be supplied to the second node n2 via the second transistor T2. At the same time, the data voltage Vdata may be supplied to the first node n1 via the first transistor T1. At this time, the data voltage Vdata may be a refresh voltage Vrefresh2 that is the same as or similar to the refresh voltage Vrefresh1. For example, the refresh voltages Vrefresh1 and Vrefresh2 may be 0 V, but are not limited thereto. In this instance, the charge voltage of the capacitor Cstg between the first node n1 and the second node n2 during the previous frame may be discharged to become the refresh voltage Vrefresh1 and Vrefresh2.

When the first transistor T1 and the second transistor T2 are turned on by the gate signal having a high level during the second section, the threshold compensation voltage (Vth_Com of FIG. 11) as the reference voltage Vref may be supplied to the second node n2 via the second transistor T2. At the same time, the data voltage Vdata_R may be supplied to the first node n1 via the first transistor T1. In this instance, the data voltage Vdata_R may be charged to the capacitor Cstg, and a driving current may flow to the third transistor T3 by the charging voltage of the capacitor Cstg. Accordingly, since a threshold voltage of the third transistor T3 is compensated by the threshold compensation voltage (Vth_Com of FIG. 11), the size of the driving current may be determined by the data voltage Vdata_R, so that there is no need to consider a deviation between the threshold voltages of the third transistors T3 of the plurality of subpixels PX1, PX2, and PX3, thereby improving the image quality.

The third transistor T3 and the capacitor Cstg may generate a driving current to drive the semiconductor light-emitting element 150-1, so that it may be called a driving transistor. The capacitor Cstg may charge a voltage for generating the driving current. This charging voltage may be obtained from the data voltage Vdata_R. The size of the driving current varies depending on the data voltage Vdata_R and/or the potential difference between the high-potential voltage line VDDL and the low-potential voltage line VSSL, and the luminance of the color light of the semiconductor light-emitting element 150-1 may also vary due to the driving current that varies in this way.

The third transistor T3 may start to turn on when the charge voltage of the capacitor Cstg is at least greater than the threshold voltage of the third transistor T3, and accordingly, a driving current path may be formed that flows from the high-potential voltage line VDDL to the low-potential voltage line VSSL via the third transistor T3 and the semiconductor light-emitting element 150-1. The size of the driving current may increase as the charge voltage of the capacitor Cstg is greater than the threshold voltage of the third transistor T3. The fourth transistor T4 may be turned on so that the driving current generated in the subpixel circuit 230 may be supplied to the semiconductor light-emitting element 150-1. The turn-on point in time of the fourth transistor T4 may be the same as the point in time when the data voltage Vdata_R is supplied to the capacitor Cstg via the first transistor T1, but is not limited thereto.

The third transistor T3 may be connected between the first node n1, the high-potential voltage line VDDL, and the second node n2. The third transistor T3 may comprise a gate terminal connected to the first node n1, a source terminal connected to the high-potential voltage line VDDL, and a drain terminal connected to the second node n2.

The capacitor Cstg may be connected between the first node n1 and the second node n2. The first node n1 may be connected to the first node n1 of the capacitor Cstg, and the second node n2 may be connected to the second node n2 of the capacitor Cstg.

Meanwhile, the low-potential voltage line VSSL may be connected to the second assembly wiring 322.

The high-potential voltage line VDDL may be called a first power line, and the low-potential voltage line VSSL may be called a second power line.

Meanwhile, the subpixel circuit 230 may comprise a fourth transistor T4. The fourth transistor T4 may be an N-type transistor, but is not limited thereto.

The fourth transistor T4 may control the supply of the driving current of the subpixel circuit 230 to the semiconductor light-emitting element 150-1. The fourth transistor T4 may control the AC signal ACS or the DC signal DCS supplied from the signal supply unit 400 to prevent it from flowing back into the subpixel circuit 230.

The fourth transistor T4 may be connected between the fourth signal line 234, the second node n2, and the third node n3. The fourth transistor T4 may comprise a gate terminal connected to the fourth signal line 234, a source terminal connected to the second node n2, and a drain terminal connected to the third node n3.

The fourth transistor T4 may be turned on/off by a protection control signal Vsw. For example, the fourth transistor T4 may be turned on by the protection control signal Vsw of a high level, and the fourth transistor T4 may be turned off by the protection control signal Vsw of a low level.

As an example, even if the subpixel circuit 230 is provided on the substrate 310 during self-assembly, the subpixel circuit 230 may not be connected to the first assembly wiring 321.

As another example, even if the subpixel circuit 230 provided on the substrate 310 during self-assembly is connected to the first assembly wiring 321, the fourth transistor T4 may be turned off by the protection control signal Vsw having a low level. In this instance, even if the AC signal ACS output from the signal supply unit 400 connected to the first assembly wiring 321 is supplied to the first assembly wiring 321 and the second assembly wiring 322, since the fourth transistor T4 is turned off, the AC signal ACS cannot flow back to the subpixel circuit 230 and may only be supplied to the first assembly wiring 321 and the second assembly wiring 322. Accordingly, since a DEP force of a preset intensity is formed on the first assembly wire 321 and the second assembly wire 322 by the corresponding AC signal ACS and the intensity of the DEP force is small, the problem of a decrease in the assembly rate of the semiconductor light-emitting device 150-1 can be solved. In addition, since the AC signal ACS is blocked by the fourth transistor T4 and does not flow into the subpixel circuit 230, it may be prevented from affecting the subpixel circuit 230 or damaging the circuits included in the subpixel circuit 230.

When the semiconductor light-emitting element 150-1 emits light for inspection after product assembly or for a customer to watch a display image, a driving current may be generated in the subpixel circuit 230 and the fourth transistor T4 may be turned on by a protection control signal Vsw having a high level, so that the driving current may flow to the semiconductor light-emitting element 150-1 via the fourth transistor T4 and the first assembly wiring 321. Accordingly, the semiconductor light-emitting element 150-1 may emit light by the driving current. At this time, since no signal is output from the signal supply unit 400, the light emission of the semiconductor light-emitting element 150-1 may be not affected by the AC signal ACS or the DC signal DCS output from the signal supply unit 400, so that the image quality can be improved and the reliability can be enhanced.

In order to stabilize before light emission after product assembly or when the image quality degrades due to long-term watching of the customer's display image, the fourth transistor T4 may be turned off by the protection control signal Vsw having a low level. In addition, the DC signal DCS output from the signal supply unit 400 may be supplied to the semiconductor light-emitting element 150-1 via the first assembly wiring 321 and the second assembly wiring 322 of each of the plurality of subpixels PX1, PX2, and PX3 included in the display region (DA of FIG. 7). By performing aging for a certain period of time, the luminance deviation between the plurality of subpixels PX1, PX2, and PX3 may be reduced or eliminated, so that the image quality can be improved.

In particular, an aging request by a customer may be made through a remote control device such as a remote controller. In addition, an aging operation button may be installed in hardware on a part of a display device 300 according to an embodiment, or an item, i.e., an icon, that may execute an aging operation button may be displayed on the screen of the display. Alternatively, an aging request may be transmitted to a control unit or a timing controller by clicking an icon displayed on the screen of the display using a remote controller. The control unit or the timing controller may generate an aging control signal in response to the aging request, and a DC signal DCS may be transmitted from the signal supply unit 400 to each of the semiconductor light-emitting elements 150-1 of the plurality of subpixels PX1, PX2, and PX3 according to the aging control signal.

Meanwhile, even if the DC signal DCS is supplied from the signal supply unit 400 to the first assembly wiring 321 and the second assembly wiring 322 for aging, since the fourth transistor T4 is turned off, the DC voltage may not flow back to the sub-pixel circuit 230, thereby preventing damage to electronic components such as transistors of the sub-pixel circuit 230. In addition, by blocking the loss of the DC signal DCS, aging may be performed without interference, so that the luminance deviation between multiple sub-pixels PX1, PX2 and PX3 can be reduced.

Meanwhile, the subpixels PX1, PX2, and PX3 according to the first embodiment may comprise the switching unit 440 of the signal supply unit 400.

The switching unit 440 may be included in the subpixels PX1, PX2, and PX3. The switching unit 440 may be included in the subpixels PX1, PX2, and PX3 instead of the signal supply unit 400. The structure of the switching unit 440 has been described above, so that a detailed description thereof will be omitted.

FIG. 11 is a signal waveform diagram for an operation of a first subpixel.

As illustrated in FIG. 7 and FIG. 9 to FIG. 11, the embodiment may be operated at various different points in time.

### During Self-Assembly

A semiconductor light-emitting element 150-1 corresponding to each of the plurality of subpixels PX1, PX2, and PX3 on the backplane may be assembled. The backplane is a general term for a substrate equipped with various electronic circuits or electronic components, but not yet equipped with the semiconductor light-emitting element 150-1. In this instance, the subpixel circuit 230 does not operate, and a DEP force may be formed on the first assembly wiring 321 and the second assembly wiring 322 by the AC signal ACS from the signal supply unit 400, and the semiconductor light-emitting element 150-1 may be assembled to the corresponding subpixels PX1, PX2, and PX3 by the DEP force.

### During Inspection Before Product Shipment

An aging process and a lighting inspection may be performed. First, as an aging process, the subpixel circuit 230 does not operate except that the fourth transistor T4 is turned off, and a plurality of subpixels PX1, PX2, and PX3 included in the display region DA may be aged by a DC signal DCS from the signal supply unit 400, so that the semiconductor light-emitting element 150-1 in an unstable state may be changed to a stable state in the assembly hole 340H1. In addition, the luminance deviation between the plurality of subpixels PX1, PX2, and PX3 may be reduced or eliminated by the aging process. As a lighting inspection process, a driving current may be generated in the subpixel circuit 230, so that the semiconductor light-emitting element 150-1 may emit light by the driving current. At this time, no signal may be supplied from the signal supply unit 400 to the subpixels PX1, PX2, and PX3. By checking whether the semiconductor light-emitting element 150-1 lights up, the lighting rate, the lighting defect rate, the yield, etc. may be obtained.

### When the Image Quality Degrades Due to Long-Term Display by the Customer

Since the image quality degrades, an aging process may be performed to solve the degradation. For example, an aging activation command may be directly transmitted to the control unit or the timing controller using a remote controller. Or, an item that may be clicked by the remote controller may be displayed on the screen of the display. The item may comprise an aging activation command. When the item displayed on the display screen by the remote controller is clicked, the aging activation command may be transmitted to the control unit or the timing controller.

Hereinafter, operations at different points in time will be described with reference to FIGS. 11 to 18.

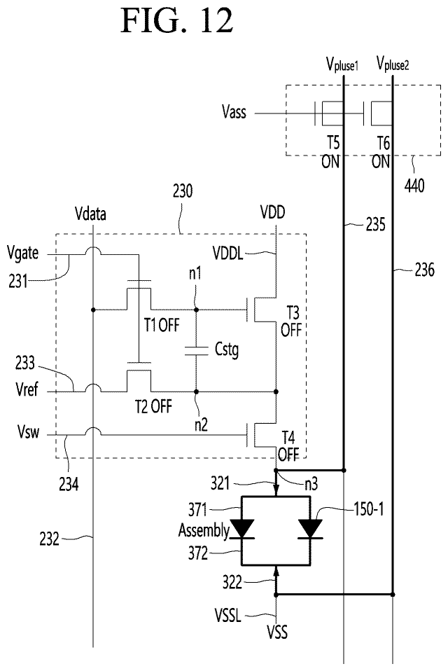

FIG. 12 illustrates an operation of a first subpixel during self-assembly.

A backplane may be provided for self-assembly. As described above, the backplane is a general term for a substrate that is equipped with various electronic circuits or electronic components, but is not yet equipped with a semiconductor light-emitting element 150-1.

In the case of excluding the semiconductor light emitting element 150-1, the second insulating layer 360, the first electrode wiring 371, and the second electrode wiring 372 in FIG. 9, it can be called a backplane. In other words, the backplane may mean that the first assembly wiring 321, the second assembly wiring 322, the first insulating layer 330, and the partition wall 340 are disposed on the substrate 310. In this instance, the signal supply unit 400 may be connected to the first assembly wiring 321 and the second assembly wiring 322. At this time, a part of the signal supply unit 400, that is, the switching unit 440, may be disposed on the subpixels PX1, PX2, and PX3, but is not limited thereto.

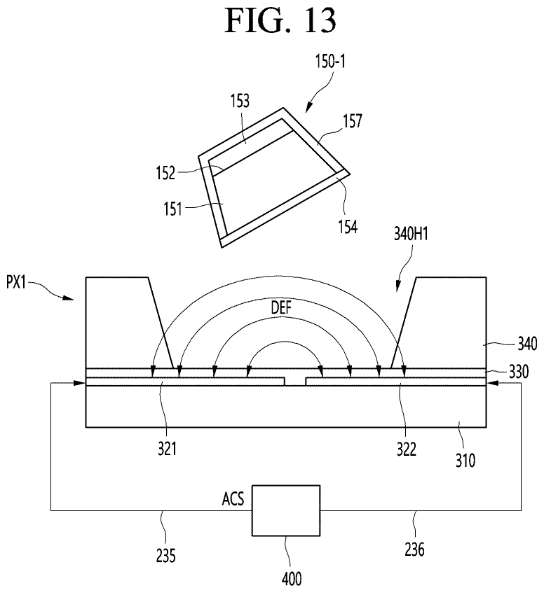

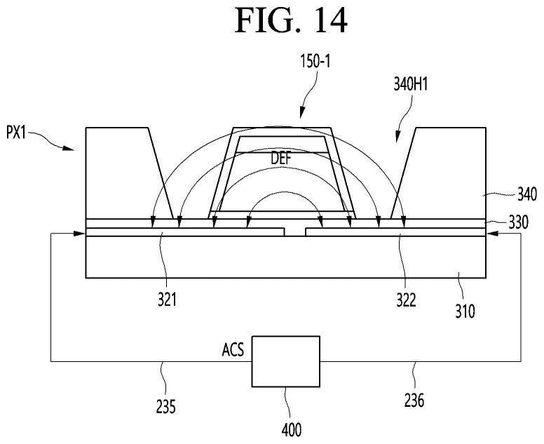

Referring to FIG. 8, FIG. 12 and FIG. 13, for self-assembly, the fifth transistor T5 and the sixth transistor T6 of the switching unit 440 of the signal supply unit 400 may be turned on by a predetermined control signal, so that the AC signal ACS selected by the signal selector 430 may be supplied to the first assembly wiring 321 and the second assembly wiring 322 through the fifth signal line 235 and the sixth signal line 236. A DEP force may be formed in the assembly hole 340H1 on the first assembly wiring 321 and the second assembly wiring 322 by the AC signal ACS, the permittivity of the first insulating layer 330, the fluid, etc. Accordingly, as illustrated in FIG. 14, the semiconductor light-emitting element 150-1 flowing in the fluid may pass over the assembly hole 340H1 of the subpixels PX1, PX2, and PX3, and the semiconductor light-emitting element 150-1 may be assembled into the assembly hole 340H1 by the DEP force formed in the assembly hole 340H1. That is, the semiconductor light-emitting element 150-1 may be pulled by the DEP force and inserted into the assembly hole 340H1. The semiconductor light-emitting element 150-1 may be continuously fixed by the DEP force even within the assembly hole 340H1.

Meanwhile, the subpixel circuit 230 of the subpixels PX1, PX2, and PX3 defined on the backplane may not be connected to the first assembly wiring 321. Or, the subpixel circuit 230 may be connected to the first assembly wiring 321, but the fourth transistor T4 may be turned off by the protection control signal Vsw having a high level. In this instance, even if the AC signal ACS is supplied from the signal supply unit 400 to the first assembly wiring 321 and the second assembly wiring 322, the AC signal ACS may be blocked by the fourth transistor T4, thereby preventing damage to the electronic circuit or electronic components of the subpixel circuit 230.

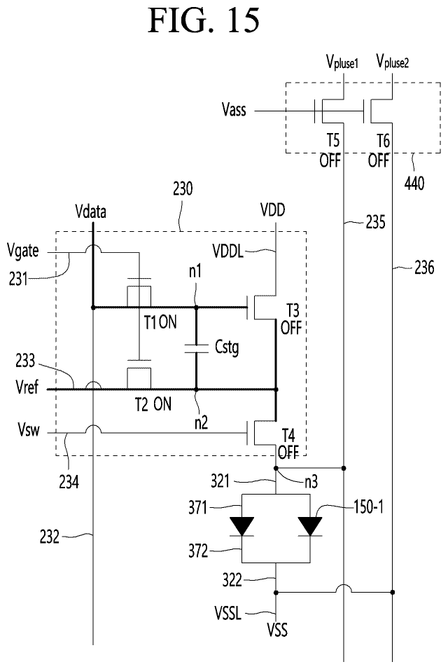

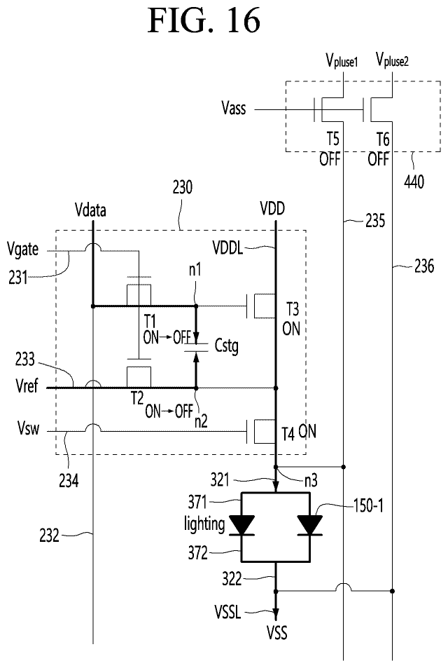

FIGS. 15 and 16 illustrate a light-emitting operation of a semiconductor light-emitting element of a first subpixel.

The light-emitting operation may be repeatedly operated in a cycle of one frame comprising a first section and a second section. As illustrated in FIG. 11, the semiconductor light-emitting element 150-1 of the first subpixel PX1 may emit light for each frame that is repeated, such as a first frame, a second frames, etc.

During the first section, the subpixels PX1, PX2, and PX3 or the subpixel circuit 230 of the subpixels PX1, PX2, and PX3 may be initialized. During the second section, the semiconductor light-emitting element 150-1 may be made to emit light based on a driving current proportional to the square of the data voltage Vdata_R by compensating for the threshold voltage of the third transistor T3. The second section may also be divided into a second-first section in which a threshold compensation voltage (Vth_Com of FIG. 11) for compensating for the threshold voltage of the third transistor T3 is charged to the capacitor Cstg, and a second-second section in which the semiconductor light-emitting element 150-1 emits light based on a driving current proportional to the square of the data voltage Vdata_R by compensating for the threshold voltage of the third transistor T3 by the threshold voltage charged to the capacitor Cstg.

First, as illustrated in FIG. 11 and FIG. 15, during the first section, the first transistor T1 and the second transistor T2 may be turned on by a gate signal having high state, so that the capacitor Cstg may be charged to be discharged to the refresh voltage Vrefresh1 and Vrefresh2. That is, the refresh voltage Vrefresh2 included in the data voltage Vdata may be supplied to the first node n1 via the first transistor T1, and the refresh voltage Vrefresh1 included in the reference voltage Vref may be supplied to the second node n2 via the second transistor T2. Accordingly, the capacitor Cstg connected between the first node n1 and the second node n2 may be discharged to the refresh voltage Vrefresh1 and Vrefresh2. That is, a voltage remaining in the capacitor Cstg due to an operation of the previous frame may be discharged to the refresh voltage Vrefresh1 and Vrefresh2. The capacitor Cstg of each subpixel circuit 230 of the plurality of subpixels PX1, PX2, and PX3 included in the display region DA illustrated in FIG. 7 may be discharged to the same refresh voltage Vrefresh1 and Vrefresh2, but is not limited thereto.

Thereafter, as illustrated in FIG. 11 and FIG. 16, the first transistor T1 and the second transistor T2 may be turned on by a gate signal having high state during the second section, so that the data voltage Vdata_R may be supplied to the first node n1 via the first transistor T1, and the threshold compensation voltage Vth_com may be supplied to the second node n2 via the second transistor T2.

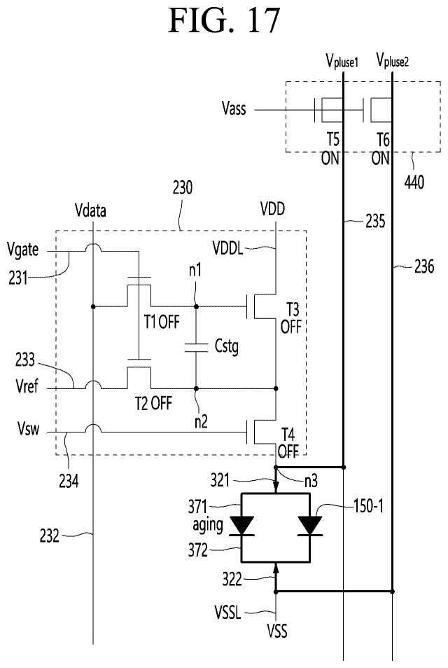

FIG. 17 illustrates an aging operation of a semiconductor light-emitting element of a first subpixel.

As described above, aging may be performed during inspection before product launch or when the image quality degrades due to long-term display by a customer.

As illustrated in FIG. 17, the fifth transistor T5 and the sixth transistor T6 of the switching unit 440 of the signal supply unit 400 may be turned on, so that the DC signal DCS may be supplied to the semiconductor light-emitting element 150-1 through the first assembly wiring 321 and the second assembly wiring 322. The DC signal DCS may be supplied to the subpixels PX1, PX2, and PX3 included in the display region DA illustrated in FIG. 7 as well as the first subpixel PX1.

Since the DC signal DCS is supplied to the semiconductor light-emitting element 150-1 of each of the plurality of subpixels PX1, PX2, and PX3 for a predetermined period of time, the luminance deviation between the plurality of subpixels PX1, PX2, and PX3 may be reduced or eliminated, so that the image quality can be improved.

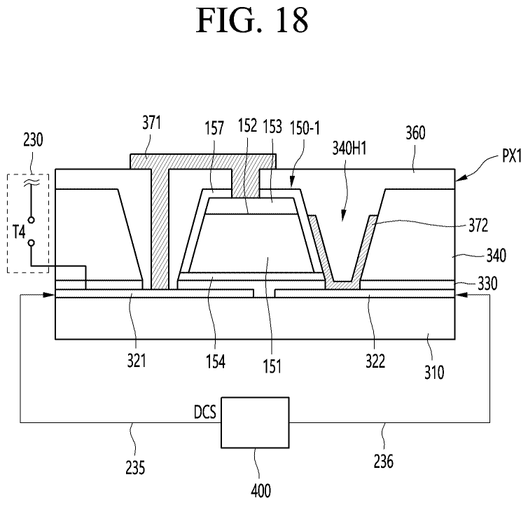

Meanwhile, each of the first transistor T1, the second transistor T2, the third transistor T3, and the fourth transistor T4 may be turned off. In particular, as illustrated in FIG. 18, since the fourth transistor T4 is turned off, the DC signal DCS supplied to the first assembly wiring 321 and the second assembly wiring 322 via the fifth transistor T5 and the sixth transistor T6 of the switching unit 440 may be blocked by the fourth transistor T4 and may not flow into the subpixel circuit 230, so that damage to the electronic circuit or electronic components of the subpixel circuit 230 can be prevented.

Meanwhile, in the case where the image quality degrades due to long-term display, an aging activation command may be input to the input interface (500 of FIG. 7) via a remote control device. When an aging activation command is input, the fifth transistor T5 and the sixth transistor T6 of the switching unit 440 may be turned on in response to the aging activation command, respectively, so that the DC signal DCS may be supplied to the subpixels PX1, PX2, and PX3.

Although FIG. 17 illustrates that the DC signal DCS is supplied to the first subpixel PX1, the DC signal DCS may be supplied to each of the plurality of subpixels PX1, PX2, and PX3 of the display region DA illustrated in FIG. 7. Since the DC signal DCS is supplied to the semiconductor light-emitting elements 150-1 of each of the plurality of subpixels PX1, PX2, and PX3 and aged for a predetermined period of time, the luminance deviation of each of the plurality of subpixels PX1, PX2, and PX3 may be minimized or eliminated, so that the image quality can be improved. Therefore, whenever the user determines that the image quality is not good while watching the display, the user may watch the display to have improved image quality through aging using the remote control device.

Meanwhile, the switching unit 440 of the signal supply unit 400 has been described as being positioned in the first subpixel PX1.

However, the switching unit 440 of the signal supply unit 400 may be provided in the non-display region NDA. The switching unit 440 may comprise the fifth transistor T5 and the sixth transistor T6. When the fifth transistor T5 and the sixth transistor T6 are provided in not only the first subpixel PX1 but also each of the plurality of subpixels PX1, PX2, and PX3 of the display region DA illustrated in FIG. 7, it may be a significant limitation in reducing the sizes of the subpixels PX1, PX2, and PX3.

Accordingly, as illustrated in FIG. 19, the switching unit 440 of the signal supply unit 400 may be provided in the non-display region NDA. Although not illustrated in the drawing, the non-display region NDA may be defined on the lower surface of the substrate rather than the upper surface of the substrate, or may be defined on another member separate from the substrate.

As described above, the AC signal generator 410, the DC signal generator 420, and the signal selector 430 of the signal supply unit 400 may be provided in the non-display region NDA. In this instance, the switching unit 440 may be positioned adjacent to the signal selector 430, but is not limited thereto. For example, the AC signal generator 410, the DC signal generator 420, and the signal selector 430 of the signal supply unit 400, as well as the switching unit 440, may be provided in the non-display region NDA on the right side of the display region DA illustrated in FIG. 7, but is not limited thereto.

The switching unit 440 may comprise the fifth transistor T5 and the sixth transistor T6. The fifth transistor T5 and the sixth transistor T6 may be connected to the signal selector 430. The switching unit 440 provided in the non-display region NDA may be connected to each of the plurality of subpixels PX1, PX2, and PX3 included in the display region DA. Accordingly, when the DC signal DCS output through the switching unit 440 is supplied to each of the plurality of subpixels PX1, PX2, and PX3 included in the display region DA during self-assembly or aging, the plurality of semiconductor light-emitting elements 150-1 may be assembled to each of the plurality of subpixels PX1, PX2, and PX3, or the semiconductor light-emitting elements 150-1 of each of the plurality of subpixels PX1, PX2, and PX3 may be aged, thereby improving the image quality.

The fifth transistor T5 and the sixth transistor T6 may be formed by the same semiconductor process as the first transistor T1, the second transistor T2, the third transistor T3, and the fourth transistor T4, but are not limited thereto.

Therefore, since the switching unit 440 is provided in the non-display region NDA rather than the plurality of subpixels PX1, PX2, and PX3 included in the display region DA, the sizes of the subpixels PX1, PX2, and PX3 may be reduced, thereby implementing high resolution.

Meanwhile, the display device described above may be a display panel. That is, in the embodiment, the display device and the display panel may be understood to have the same meaning. In the embodiment, the display device in a practical sense may comprise a display panel and a controller (or processor) capable of controlling the display panel to display an image.

The above detailed description should not be construed as limiting in all respects and should be considered illustrative. The scope of the embodiment should be determined by reasonable interpretation of the appended claims, and all changes within the equivalent range of the embodiment are included in the scope of the embodiment.

### INDUSTRIAL APPLICABILITY

The embodiment may be adopted in the display field that display images or information. The embodiment may be adopted in the display field that display images or information using a semiconductor light-emitting element. The semiconductor light-emitting element may be a micro-level semiconductor light-emitting element or a nano-level semiconductor light-emitting element.

For example, the embodiment may be adopted in a TV, a signage, a mobile terminal such as a mobile phone or a smart phone, a computer display such as a laptop or a desktop, a head-up display (HUD) for an automobile, a backlight unit for a display, a display for VR, AR or mixed reality (MR), a light source, etc.

1. A display device, comprising:
a substrate comprising a plurality of pixels, each of the plurality of pixels comprising a plurality of subpixels;
a subpixel circuit in each of the plurality of subpixels;
a first assembly wiring and a second assembly wiring in each of the plurality of subpixels;
a partition wall having an assembly hole on the first assembly wiring and the second assembly wiring;
a semiconductor light-emitting element in the assembly hole; and
a signal supply unit configured to be connected to the first assembly wiring and the second assembly wiring and to selectively supply an AC signal and a DC signal,
wherein the subpixel circuit is configured to be connected to one of the first assembly wiring and the second assembly wiring.
wherein the first assembly wiring is configured to be connected to a first side of the semiconductor light-emitting element, and the second assembly wiring is configured to be connected to a second side of the semiconductor light-emitting element,
wherein the subpixel circuit comprises:
a first transistor between a first signal line, a second signal line, and a first node;
a second transistor between the first signal line, a third signal line, and a second node;
a third transistor between the first node, a power line, and the second node;
a fourth transistor between a fourth signal line, the second node, and a third node; and
a capacitor between the first node and the second node, and
wherein, when the semiconductor light-emitting element is aged, the fourth transistor is turned off, and the signal supply unit is configured to supply the DC signal to the first assembly wiring and the second assembly wiring.

2. The display device of claim 1, wherein, when the semiconductor light-emitting element is self-assembled, the signal supply unit is configured to supply the AC signal to the first assembly wiring and the second assembly wiring.

3. (canceled)

4. The display device of claim 1, wherein, when the semiconductor light-emitting element emits light, the subpixel circuit is configured to supply a driving current to one of the first assembly wiring and the second assembly wiring.

5. (canceled)

6. (canceled)

7. (canceled)

8. The display device of claim 1, wherein the signal supply unit comprises:
an AC signal generator configured to generate the AC signal;
a DC signal generator configured to generate the DC signal;
a signal selector configured to selectively output the AC signal and the DC signal; and
a switching unit configured to control supply of an output signal of the signal selector.

9. The display device of claim 8, wherein the switching unit comprises:
a fifth transistor configured to switch supply of a first voltage of the output signal to the first assembly wiring; and
a sixth transistor configured to switch supply of a second voltage of the output signal to the second assembly wiring.

10. The display device of claim 9, wherein, when the semiconductor light-emitting element is self-assembled, the fifth transistor and the sixth transistor are turned on to supply the AC signal selected by the signal selector.

11. The display device of claim 9, wherein, when the semiconductor light-emitting element is aged, the fifth transistor and the sixth transistor are turned on to supply the DC signal selected by the signal selector.

12. The display device of claim 9, wherein, when the semiconductor light-emitting element emits light, the fifth transistor and the sixth transistor are turned off to block supply of the AC signal or the DC signal selected by the signal selector.

13. The display device of claim 8, wherein the AC signal generator, the DC signal generator, and the signal selector are provided on a non-display region.

14. The display device of claim 8, wherein the switching unit is provided on a non-display region.

15. The display device of claim 8, wherein the switching unit is provided in each of the plurality of subpixels.

16. The display device of claim 1, comprising:
an input interface,
wherein the signal supply unit is configured to supply the DC signal to the semiconductor light emitting element in response to an aging signal through the input interface.
